(19) United States
(12) Patent Application Publication
(10) Pub. No.: US 2013/0207082 A1
(43) Pub. Date: Aug. 15, 2013

(54) ORGANIC LIGHT-EMITTING DEVICE HAVING IMPROVED EFFICIENCY CHARACTERISTICS AND ORGANIC LIGHT-EMITTING DISPLAY APPARATUS INCLUDING THE SAME

(71) Applicants: Hwan-Hee CHO, Yongin-city (KR); Kwan-Hee LEE, Yonging-sity (KR); Chang-Woong CHU, Yongin-city (KR); Moon-Jae LEE, Yongin-city (KR); Jae-Hyun KWAK, Yongin-city (KR); Young-Ho PARK, Yongin-city (KR); Ji-Hyun SEO, Yongin-city (KR)

(72) Inventors: Hwan-Hee CHO, Yongin-city (KR); Kwan-Hee LEE, Yonging-sity (KR); Chang-Woong CHU, Yongin-city (KR); Moon-Jae LEE, Yongin-city (KR); Jae-Hyun KWAK, Yongin-city (KR); Young-Ho PARK, Yongin-city (KR); Ji-Hyun SEO, Yongin-city (KR)

(73) Assignee: Samsung Display Co., Ltd., Yonging-City (KR)

(21) Appl. No.: 13/600,037

(22) Filed: Aug. 30, 2012

(30) Foreign Application Priority Data
Feb. 14, 2012 (KR) 10-2012-0014825

(51) Int. Cl. H01L 51/54

(52) U.S. Cl. 257/40; 257/E51.026

(57) ABSTRACT

An organic light-emitting device including a first electrode, a second electrode opposite to the first electrode, a phosphorescent layer disposed between the first electrode and the second electrode, an electron transport layer disposed between the phosphorescent emission layer and the second electrode, and an electron control layer disposed between the phosphorescent emission layer and the electron transport layer. An organic light-emitting display apparatus including the OLED.

### CROSS-REFERENCE TO RELATED PATENT APPLICATION

This application claims the benefit of Korean Patent Application No. 10-2012-0014825, filed on Feb. 14, 2012, in the Korean Intellectual Property Office, the disclosure of which is incorporated herein in its entirety by reference.

### BACKGROUND

1. Field

The present embodiments relate to an organic light-emitting device (OLED) having improved efficiency characteristics, and more particularly, to an OLED of which luminous efficiency characteristics are improved according to luminance. Also, the present embodiments relate to an OLED apparatus including the OLED of which luminous efficiency characteristics are improved in a black state.

2. Description of the Related Technology

Organic light-emitting devices (OLEDs) are self-emission devices, have a wide viewing angle, a high contrast ratio, a short response time, and excellent luminance, driving voltage, and response speed characteristics, and enable generation of multi-color images.

In a typical OLED, an anode is formed on a substrate, and a hole transport layer, an emission layer, an electron transport layer, and a cathode are sequentially formed in this stated order on the anode. In this regard, the hole transport layer, the emission layer, and the electron transport layer are organic film layers including organic compounds. When a voltage is applied between the anode and the cathode, holes injected from the anode pass the hole transport layer and migrate toward the emission layer, and electrons injected from the cathode pass the electron transport layer and migrate toward the emission layer. Carriers such as the holes and electrons are recombined in the emission layer to generate excitons, and then the excitons change from an excited state to a ground state, thereby generating light.

The most important factor to determine luminous efficiency in an OLED is light emitting material. Though fluorescent materials have been widely used up to the present as the light emitting material, development of a phosphorescent material, from the aspect of the mechanism of electroluminescence, is one of the best ways to improve the luminous efficiency up to 4-fold, theoretically.

The OLED using a phosphorescent material shows a very high efficiency compared to the OLED using a fluorescent material at a low luminance region. Particularly, since the OLED using a phosphorescent material has a high luminous efficiency at a region where low current flows, a phenomenon of an organic light-emitting display apparatus emitting weak green or red light due to leakage current when the apparatus needs to display a black state may occur. In order to overcome such problem, a method of inserting a layer which slows down hole transportation between a hole transport layer and an emission layer or a method of applying pure metal to an electron injection layer have been used.

However, even with the above methods, low luminance state efficiency characteristics of the OLED using a phosphorescent material has not achieved a satisfactory level, thereby can be improved.

### SUMMARY

The present embodiments provide an organic light-emitting device (OLED) which has an excellent luminous efficiency at a high luminance region and a low luminous efficiency at a low luminance region.

The present embodiments also provide an organic light-emitting display apparatus including the OLED and thus suppressing emission of red and green light in a black state.

According to an aspect of the present embodiments, there is provided an organic light-emitting device (OLED) including a first electrode; a second electrode opposite to the first electrode; a phosphorescent layer disposed between the first electrode and the second electrode; an electron transport layer disposed between the phosphorescent emission layer and the second electrode; and an electron control layer disposed between the phosphorescent emission layer and the electron transport layer, wherein the phosphorescent emission layer includes a host material and a dopant material, and the electron control layer includes an electron control material, wherein a highest occupied molecular orbital (HOMO) energy level of the host material (EH_{H}), a lowest unoccupied molecular orbital (LUMO) energy level of the host material (EL_{H}), a HOMO energy level of the electron control material (EH_{C}), and a LUMO energy level of the electron control material (EL_{C}) satisfy both relationships of |EH_{H}−EH_{C}|≦0.3 eV and |EL_{H}−EL_{C}|≦0.5 eV, wherein a thickness of the electron control layer is from about 50 Å to about 450 Å.

EH_{H}, EL_{H}, EH_{C}, and EL_{C} may satisfy both relationships of 0≦EH_{H}−EH_{C}≦0.3 eV and 0≦EL_{H}−EL_{C}≦0.5 eV.

An electron mobility of the electron control material may be greater than or same as a hole mobility.

EH_{C} may be in a range from −5.2 eV to −6.1 eV.

EL_{C} may be in a range from −2.5 eV to −3.2 eV.

A content of the electron control material may be in a range from about 30 weight % (wt %) to about 100 wt % based on a total weight of the electron control layer.

A thickness ratio of the electron transport layer and the electron control layer may be in a range from 5:1 to 5:10.

According to another aspect of the present embodiments, there is provided an OLED including a first electrode; a second electrode opposite to the first electrode; a phosphorescent layer disposed between the first electrode and the second electrode; an electron transport layer disposed between the phosphorescent emission layer and the second electrode; an electron control layer disposed between the phosphorescent emission layer and the electron transport layer; and an electron blocking layer disposed between the phosphorescent emission layer and the first electrode, wherein the phosphorescent emission layer includes a host material and a dopant material, the electron control layer includes an electron control material, and the electron blocking layer includes an electron blocking material, wherein EH_{H}, EL_{H}, EH_{C}, EL_{C} and a LUMO energy level of the electron blocking material EL_{B} satisfy relationships of |EH_{H}−EH_{C}|≦0.3 eV, |EL_{H}−EL_{C}|≦0.5 eV, and EL_{B}>EL_{H}, wherein a thickness of the electron control layer is from about 50 Å to about 450 Å.

The electron blocking material may include at least one of a triphenylamine derivative, a carbazole derivative, and a spirobifluorene derivative.

A thickness of the electron blocking layer may be from about 10 Å to about 1000 Å.

EH_{H}, EL_{H}, EH_{C}, and EL_{C} may satisfy relationships of 0≦EH_{H}−EH_{C}≦0.3 eV and 0≦EL_{H}−EL_{C}≦0.5 eV.

An electron mobility of the electron control material may be greater than or same as a hole mobility.

EH_{C} may be in a range from −5.2 eV to −6.1 eV.

EL_{C} may be in a range from −2.5 eV to −3.2 eV.

A content of the electron control material may be in a range from about 30 wt % to about 100 wt % based on a total weight of the electron control layer.

A thickness ratio of the electron transport layer and the electron control layer may be in a range from 5:1 to 5:10.

The electron control material may include a compound represented by Formula 1 below:

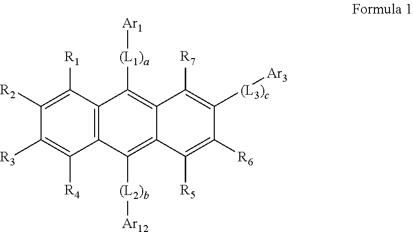

In Formula 1, R₁ to R₇, Ar₁ to Ar₃, L₁ to L₃, a, b, and c have been described in detail in the Detailed Description.

The host material may include a bipolar compound having both of a hole transport unit and an electron transport unit.

The host material may include a mixture of a bipolar compound having both of a hole transport unit and an electron transport unit and a compound having at least a hole transport unit.

The phosphorescent emission layer may emit red or green light.

The electron transport layer may include a compound represented by Formula 4 below:

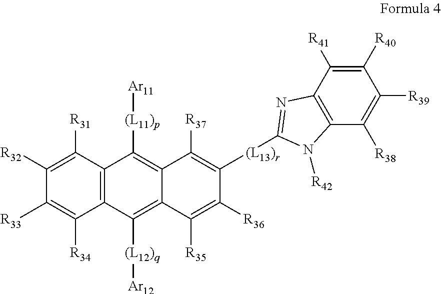

In Formula 4, R₃₁ to R₄₂, Ar₁₁ to Ar₁₂, L₁₁ to L₁₃, p, q, and r have been described in detail in the Detailed Description.

The electron transport layer may further include at least one selected from a lithium quinolate (LiQ) and Compound 101 below:

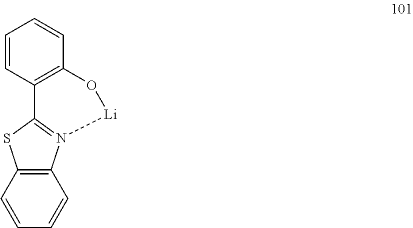

The electron transport layer may further include at least one selected from 1,4,5,8,9,12-hexaazatriphenylene hexacarbonitrile, tetracyanoquinodimethane, anthraquinone, perylenebisimide, and tetracyanoanthraquinodimethane.

The electron transport layer may further include at least one selected from at least one metal selected from Li, Cs, Na, K, Ca, Mg, Ba, and Ra; metal carbonate; metal acetate; metal benzoate; metal acetoacetate; metal acetylacetonate; and metal stearate.

The OLED may further include a hole transport layer disposed between the phosphorescent emission layer and the first electrode, wherein the hole transport layer includes a compound represented by Formula 5 below:

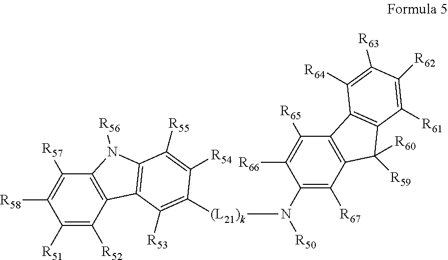

In Formula 5, R₅₀ to R₆₆, L₂₁, and k have been described in detail in the Detailed Description.

The OLED may further include a hole injection layer disposed between the hole transport layer and the first electrode, wherein the hole injection layer includes a compound represented by Formula 6 below:

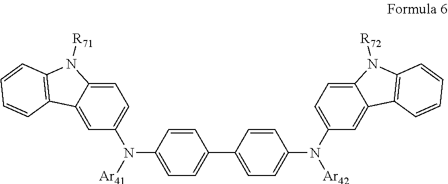

In Formula 6, Ar₄₁, Ar₄₂, R₇₁, and R₇₂ have been described in detail in the Detailed Description.

According to another aspect of the present embodiments, there is provided an organic light-emitting display apparatus including a transistor including source, drain, gate, and an active layer, and the OLED, wherein a first electrode of the OLED is electrically connected to the source or the drain.

### BRIEF DESCRIPTION OF THE DRAWINGS

The above and other features and advantages of the present embodiments will become more apparent by describing in detail example embodiments thereof with reference to the attached drawings in which:

FIG. 1 is a schematic cross-sectional view of a structure of an organic light-emitting diode (OLED) according to an embodiment;

FIG. 2 is a schematic cross-sectional view of a structure of an OLED according to another embodiment;

FIG. 3 is a schematic cross-sectional view of an OLED having a structure of a substrate/a first electrode/a hole injection layer/a hole transport layer/an emission layer/an electron control layer/an electron transport layer/an electron injection layer/a second electrode according to an embodiment;

FIG. 4 is a schematic cross-sectional view of an OLED having a structure of a substrate/a first electrode/a hole injection layer/a hole transport layer/an electron blocking layer/an emission layer/an electron control layer/an electron transport layer/an electron injection layer/a second electrode according to an embodiment;

FIG. 5 schematically illustrates HOMO energy level and LUMO energy level of each layer in the OLED shown in FIG. 3;

FIG. 6 schematically illustrates HOMO energy level and LUMO energy level of each layer in the OLED shown in FIG. 4;

FIG. 7 is a graph illustrating efficiencies of the OLEDs manufactured in Examples 1 to 6 and Comparative Examples 1 to 4 according to luminance;

FIG. 8 is a normalized graph illustrating efficiencies of the OLEDs manufactured in Examples 1 to 6 and Comparative Examples 1 to 4 according to luminance;

FIG. 9 is a graph illustrating efficiencies of the OLEDs manufactured in Examples 7 to 10 and Comparative Examples 5 to 7 according to luminance;

FIG. 10 is a normalized graph illustrating efficiencies of the OLEDs manufactured in Examples 7 to 10 and Comparative Examples 5 to 7 according to luminance;

FIG. 11 is a graph illustrating efficiencies of the OLEDs manufactured in Examples 11 to 14 and Comparative Examples 8 to 10 according to luminance; and

FIG. 12 is a normalized graph illustrating efficiencies of the OLEDs manufactured in Examples 11 to 14 and Comparative Examples 8 to 10 according to luminance.

### DETAILED DESCRIPTION

The present embodiments will now be described more fully with reference to the accompanying drawings. Expressions such as “at least one of,” when preceding a list of elements, modify the entire list of elements and do not modify the individual elements of the list.

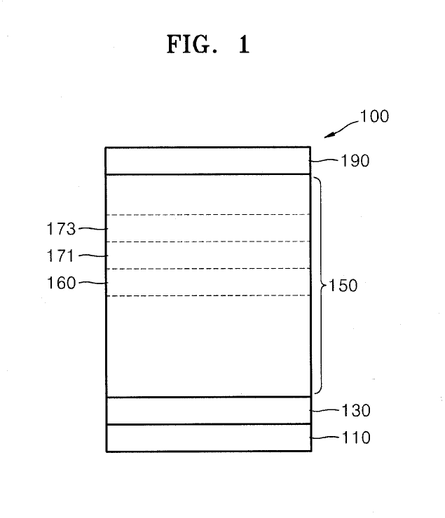

FIG. 1 is a schematic cross-sectional view of a structure of an organic light-emitting diode (OLED) 100 according to an embodiment.

Referring to FIG. 1, the OLED 100 includes a substrate 110, a first electrode 130 formed on the substrate 110, a second electrode 190 opposite to the first electrode 130, and an organic layer 150 disposed between the first electrode 130 and the second electrode 190.

The organic layer 150 includes an emission layer 160 in which holes and electrons are recombined to generate excitons and thereby light is emitted while the excitons change from an excited state to a ground state, an electron transport layer 173 disposed between the emission layer 160 and the second electrode 190, and an electron control layer 171 disposed between the emission layer 160 and the electron transport layer 173.

The emission layer 160 is a phosphorescent emission layer including a phosphorescent host material and a dopant material. The electron control layer 173 includes an electron control material.

Since a phosphorescent host material and a dopant material implement a light-emitting mechanism of which light, not heat, is emitted from a triplet excited state, an OLED using a phosphorescent host material and a dopant material in an emission layer may have a luminous efficiency that is theoretically improved up to 4 times than when a fluorescent material of which light is emitted from a singlet excited state is used.

In some embodiments, the highest occupied molecular orbital (HOMO) energy level of the host material (EH_{H}), the lowest unoccupied molecular orbital (LUMO) energy level of the host material (EL_{H}), the HOMO energy level of the electron control material (EH_{C}), and the LUMO energy level of the electron control material (EL_{C}) satisfy both relationships below:

|EH_{H}−EH_{C}|≦0.3 eV and

|EL_{H}−EL_{C}≦0.5 eV

In some embodiments, EH_{C} has a similar value with EH_{H} and the difference between absolute values of EH_{C} and EH_{H} is 0.3 eV or less.

When the difference between the absolute values of EH_{C} and EH_{H} is 0.3 eV or less, a hole blocking mechanism from an emission layer to an electron control layer at a low luminance region may be suppressed.

In some embodiments, the difference between absolute values of EL_{C} and EL_{H} is 0.5 eV or less.

When the difference between absolute values of EL_{C} and EL_{H} is 0.5 eV or less, an electron transport capacity may be appropriate, and driving voltage may not be excessively raised.

In some embodiments, the thickness of the electron control layer 171 including the electron control material is from about 50 Å to about 450 Å.

In some embodiments, the electron control layer 171 serves to control electron injection to the emission layer 160. When the thickness of the electron control layer 171 is 50 Å or greater, a luminous efficiency lowering effect occurs appropriately at a low luminance, and when the thickness is 450 Å or less, an excessive raise of driving voltage is suppressed.

The OLED 100 having such structure includes the emission layer 160, which is a phosphorescent emission layer, thereby a luminous efficiency is significantly improved, and since injection and transportation of holes and electrons at a high luminance region are smooth, the OLED 100 has an excellent luminous efficiency. However, a hole blocking mechanism is suppressed at a low luminance region due to presence of the electron control layer 171 in the OLED 100, and injection and transportation of electrons in a direction from the electron transport layer 173 to the emission layer 160 are slowed down. As a result, electrons and holes for generating exitons in the emission layer 160 at a low luminance region are unbalanced, thereby a luminous efficiency of the device is reduced.

In some embodiments, EH_{H}, EL_{H}, EH_{C}, and EL_{C} may satisfy both relationships below:

0≦EH_{H}−EH_{C}≦0.3 eV and

0≦EL_{H}−EL_{C}≦0.5 eV

In some embodiments, EH_{C} has a lower value than EH_{H}, and a difference between EH_{C} and EH_{H} is 0.3 eV or less.

Since EH_{C} is lower than EH_{H}, a luminous efficiency may be raised due to a hole blocking mechanism at a high luminance. However, since the difference is 0.3 eV or less, the luminous efficiency may be reduced as the hole blocking mechanism is suppressed at a low luminance.

Also, since EL_{C} is lower than EL_{H}, electrons may be transported smoothly. However, excessive raise of driving voltage may be suppressed since a difference between EL_{C} and EL_{H} is 0.5 eV or less.

In some embodiments, the electron mobility of the electron control material may be greater than or same as a hole mobility. In this regard, a flow or electrons in the electron control layer 171 where the electron control material is included may be slowed down. That is, the flow of electrons moving fast in the electron transport layer 173 is slowed down in a certain degree while passing through the electron control layer 171, thereby a luminous efficiency of the device at a low luminance region may be reduced.

In some embodiments, EH_{C} may be from −5.2 eV to −6.1 eV, and EL_{C} may be from −2.5 eV to −3.2 eV.

When EH_{C} and EL_{C} satisfy the ranges above, a luminous efficiency may be raised due to a hole blocking mechanism at a high luminance, and a luminous efficiency may be reduced as a hole blocking mechanism is suppressed at a low luminance.

In some embodiments, the content of the electron control material may be in a range from about 30 weight % (wt %) to about 100 wt % based on a total weight of the electron control layer 171.

The electron control layer 171 may be composed of the electron control material only or may include other materials than the electron control material. However, in order to have an improved effect of luminous efficiency characteristics according to luminance due to an electron control material, a content of the electron control material needs to be sufficient and thus may be 30 wt % or more based on the total weight of the electron control layer 171.

In some embodiments, the thickness ratio of the electron transport layer 173 and the electron control layer 171 may be in a range from about 5:1 to about 5:10.

The thickness ratio of the electron transport layer 173 and the electron control layer 171 is related to a weight ratio of a material for forming an electron transport layer included in the electron transport layer 173 and an electron control material included in the electron control layer 171 or the like, and the thickness ratio is related to an amount affected by the electron control material as well. When a thickness of the electron control layer 171 satisfies the relationship with regard to a thickness of electron transport layer 173, a luminous efficiency control effect according to luminance due to an electron control material may properly appear.

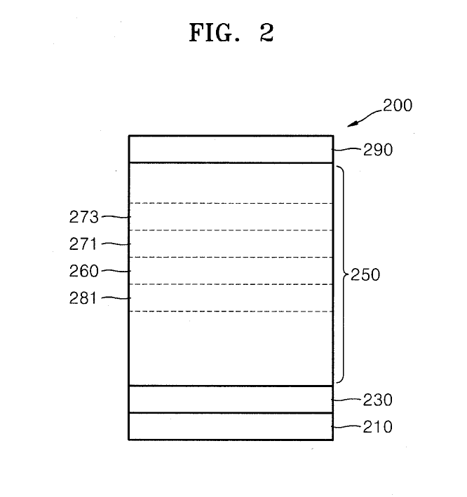

FIG. 2 is a schematic cross-sectional view of a structure of an OLED 200 according to another embodiment.

Referring to FIG. 2, the OLED 200 according to another embodiment includes a substrate 210, a first electrode 230 formed on the substrate 210, a second electrode 290 opposite to the first electrode 230, and an organic layer 250 disposed between the first electrode 230 and the second electrode 290.

The organic layer 250 includes an emission layer 260 in which holes and electrons are recombined to generate excitons and thereby light is emitted while the excitons change from an excited state to a ground state, an electron transport layer 273 disposed between the emission layer 260 and the second electrode 290, an electron control layer 271 disposed between the emission layer 260 and the electron transport layer 273, and an electron blocking layer 281 disposed between the emission layer 260 and the first electrode 230.

The emission layer 260 includes a phosphorescent host material and a dopant material, the electron control layer 173 includes an electron control material, and the electron blocking layer 281 includes an electron blocking material.

In some embodiments, EH_{H}, EL_{H}, EH_{C}, EL_{C}, and a LUMO energy level of the electron blocking material EL_{B} satisfy all three relationships below:

|EH_{H}−EH_{C}|≦0.3 eV

|EL_{H}−EL_{C}|≦0.5 eV and

EL_{B}>EL_{H}

In some embodiments, EH_{C} has a similar value with EH_{H}, and a difference between absolute values of EH_{C} and EH_{H} is 0.3 eV or less.

When the difference between the absolute values of EH_{C} and EH_{H} is 0.3 eV or less, a hole blocking mechanism from an emission layer to an electron control layer at a low luminance region may be suppressed.

In some embodiments, the difference between absolute values of EL_{C} and EL_{H} is 0.5 eV or less.

When the difference between the absolute values of EL_{C} and EL_{H} is 0.5 eV or less, an electron transport capacity may be appropriate, and driving voltage may not be excessively raised.

EL_{B} is higher than EL_{H}.

When EL_{B} is higher than EL_{H}, a mobility of electrons flowing in a direction from the emission layer 260 to the first electrode 230 may be suppressed.

In some embodiments, the thickness of the electron control layer 271 including the electron control material is from 50 Å to 450 Å.

When the thickness of the electron control layer 271 is 50 Å or greater, a luminous efficiency lowering effect occurs appropriately at a low luminance, and when the thickness is 450 Å or less, an excessive raise of driving voltage is suppressed.

In the OLED 200 having such structure, injection and transportation of holes and electrons at a high luminance region are smooth, and particularly a device luminous efficiency is excellent since the electron blocking layer 281 suppresses the electrons from transferring in a direction to the first electrode 230 over the emission layer 260.

However, in the OLED 200, a hole blocking mechanism is suppressed at a low luminance region due to a presence of the electron control layer 271, and thereby injection and transportation of electrons in a direction from the electron transport layer 273 to the emission layer 260 are slowed down. As a result, electrons and holes for generating exitons in the emission layer 260 at a low luminance region are unbalanced, thereby a luminous efficiency of the device is reduced.

In some embodiments, the electron blocking material can be a material with a high LUMO energy level, for example, including but not limited to a triarylamine-based triphenylamine derivative, a carbazole derivative, or a spirobifluorene derivative. As the electron blocking material, for example, TCTA, spiro-TAD(2,2′,7,7′-tetrakis(N,N-diphenylamino)-9,9′-spirobifluorene) or a material such as Compound 701 below may be used, or a metal complex such as Irppz or ppz2Ir(dpm) may be used:

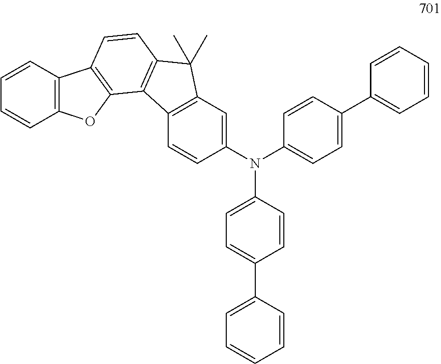 [SMILES: CC1(C)c2cc(N(c3ccc(-c4ccccc4)cc3)c3ccc(-c4ccccc4)cc3)ccc2-c2c1ccc1c2oc2ccccc21]

In some embodiments, the thickness of the electron blocking layer 281 may be from about 10 Å to about 100 Å. When the thickness of the electron blocking layer 281 is 100 Å or greater, an excellent electron blocking ability of the electron blocking layer 281 may be obtained, and when the thickness is 1000 Å or less, an excessive raise of driving voltage is suppressed. For example, the thickness of the electron blocking layer 281 may be in a range of 50 Å to 800 Å.

EH_{H}, EL_{H}, EH_{C}, and EL_{C} may satisfy relationships below:

0≦EH_{H}−EH_{C}≦0.3 eV and

0≦EL_{H}−EL_{C}≦0.5 eV

EH_{C} is lower than EH_{H}, and a difference between EH_{C} and EH_{H} is 0.3 eV or less.

Since EHC is lower than EHH, a luminous efficiency may be raised due to a hole blocking mechanism at a high luminance. However, since the difference is 0.3 eV or less, the luminous efficiency may be reduced as the hole blocking mechanism is suppressed at a low luminance.

Also, since EL_{C} is lower than EL_{H}, electrons may be transported smoothly. However, excessive raise of driving voltage may be suppressed since a difference between EL_{C} and EL_{H} is 0.5 eV or less.

In some embodiments, the electron mobility of the electron control material may be greater than or same as a hole mobility. In this regard, a flow or electrons in the electron control layer 271 where the electron control material is included may be slowed down. The flow of electrons moving fast in the electron transport layer 273 is slowed down in a certain degree while passing through the electron control layer 271, thereby a luminous efficiency of the device at a low luminance region may be reduced.

EH_{C} may be in a range, for example, from −5.2 eV to −6.1 eV, and EL_{C} may be in a range, for example, from −2.5 eV to −3.2 eV.

When EH_{C} and EL_{C} satisfy the ranges above, a luminous efficiency may be raised due to a hole blocking mechanism at a high luminance, and a luminous efficiency may be reduced as a hole blocking mechanism is suppressed at a low luminance.

In some embodiments, the content of the electron control material may be in a range from about 30 weight % (wt %) to 100 wt % based on a total weight of the electron control layer 271.

The electron control layer 271 may be composed of the electron control material only or may include other materials than the electron control material. However, in order to have an improved effect of luminous efficiency characteristics according to luminance due to an electron control material, a content of the electron control material needs to be sufficient and thus may be about 30 wt % or more based on the total weight of the electron control layer 271.

In some embodiments, the thickness ratio of the electron transport layer 273 and the electron control layer 271 may be from about 5:1 to about 5:10.

When the thickness of the electron control layer 271 satisfies the relationship with regard to a thickness of electron transport layer 273, a luminous efficiency control effect depending on luminance due to an electron control material may properly appear.

The electron control material is included in the electron control layer 171 or 271 with a content in a range from about 30 wt % to 100 wt % based on a total weight of the electron control layer 171 or 271. The electron control material is a material that controls a HOMO energy level relationship between the electron control layer 171 or 271 and the emission layer 160 or 260 and thus serves to increase rates of injection and transportation of electrons at a high luminance region and to decrease rates of injection and transportation of electrons at a low luminance region. Such electron control material may include a compound represented by Formula 1 below:

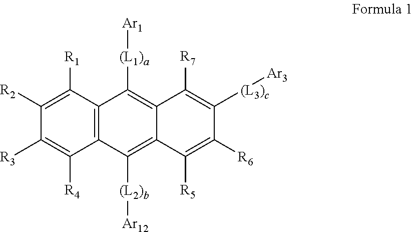

In Formula 1, R₁ to R₇ are each independently one of a hydrogen, a deuterium, a halogen, a hydroxy group, a cyano group, a nitro group, an amino group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, and a substituted or unsubstituted C₆-C₃₀ aryl group, Ar₁, Ar₂, and Ar₃ are each independently one of a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₂-C₃₀ heteroaryl group, and a group represented by —N(Q₁)(Q₂), L₁, L₂, and L₃ are each independently one of a substituted or unsubstituted C₆-C₃₀ arylene group, and a substituted or unsubstituted C₂-C₃₀ heteroarylene group, and a, b, and c are each independently one of integers of 0 to 3. In Formula 1, at least one of Ar₁, Ar₂, and Ar₃ is a substituted or unsubstituted C₂-C₃₀ heteroaryl group.

In the group represented by —N(Q₁)(Q₂), Q₁ and Q₂ are each independently one of a hydrogen, a deuterium, a halogen, a hydroxy group, a cyano group, an amino group, a nitro group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₆-C₃₀ aryl group, a substituted or unsubstituted C₆-C₃₀ aryloxy group, a substituted or unsubstituted C₆-C₃₀ arylthio group, and a substituted or unsubstituted C₂-C₃₀ heteroaryl group.

In Formula 1, when a is 0, -(L₁)ₐ- indicates a single bond, and when a is 2 or greater, a plurality of L₁ may be identical to or different from each other. Likewise, when b is 0, -(L₂)_{b}- indicates a single bond, and when b is 2 or greater, a plurality of L₂ may be identical to or different from each other. When c is 0, -(L₃)ₑ- indicates a single bond, and when c is 2 or greater, a plurality of L₃ may be identical to or different from each other.

The compound represented by Formula 1 has a HOMO energy level in a range from −5.2 eV to −6.1 eV and a LUMO energy level in a range from −2.5 eV to −3.2 eV and includes at least one C₂-C₃₀ heteroaryl group in a molecular structure of the compound an thus has a relatively excellent electron mobility.

The compound represented by Formula 1 is included in the electron control layer 171 or 271 and serves to fasten injection and transportation of electrons at a high luminance region and slow down injection and transportation of electrons at a low luminance region.

The electron control material may include at least one of the compounds represented by Formulae 2 and 3 below:

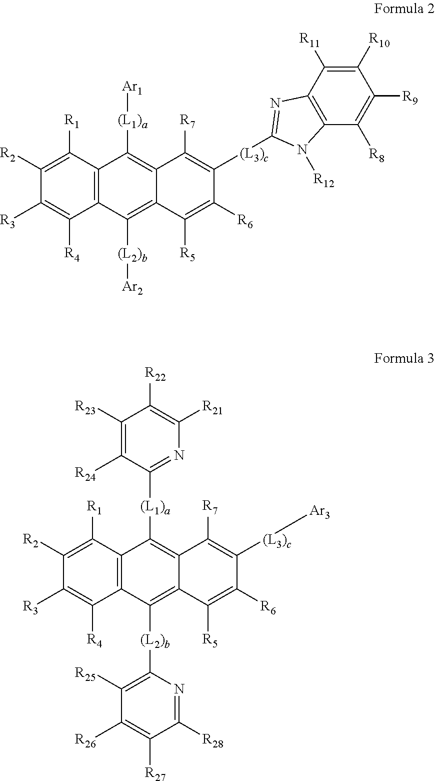

In Formulae 2 and 3, R₁ to R₁₂ and R₂₁ to R₂₈ are each independently one of a hydrogen, a deuterium, a substituted or unsubstituted methyl group, a substituted or unsubstituted ethyl group, a substituted or unsubstituted propyl group, a substituted or unsubstituted butyl group, a substituted or unsubstituted phenyl group, a substituted or unsubstituted biphenyl group, a substituted or unsubstituted naphthyl group, a substituted or unsubstituted anthryl, a substituted or unsubstituted phenanthrenyl, a substituted or unsubstituted pyrenyl group, Ar₁, Ar₂, and Ar₃ are each independently one of a substituted or unsubstituted phenyl group, a substituted or unsubstituted pentalenyl group, a substituted or unsubstituted indenyl group, a substituted or unsubstituted naphtyl group, a substituted or unsubstituted azulenyl group, a substituted or unsubstituted heptalenyl group, a substituted or unsubstituted indacenyl group, a substituted or unsubstituted acenaphtyl group, a substituted or unsubstituted fluorenyl group, a substituted or unsubstituted spirofluorenyl group, a substituted or unsubstituted phenalenyl group, a substituted or unsubstituted phenanthrenyl group, a substituted or unsubstituted anthryl group, a substituted or unsubstituted fluoranthenyl group, a substituted or unsubstituted triphenylenyl group, a substituted or unsubstituted pyrenyl group, a substituted or unsubstituted chrysenyl group, a substituted or unsubstituted naphthacenyl group, a substituted or unsubstituted picenyl group, a substituted or unsubstituted perylenyl group, a substituted or unsubstituted pentaphenyl group, a substituted or unsubstituted hexacenyl group, a substituted or unsubstituted pyrrolyl group, a substituted or unsubstituted imidazolyl group, a substituted or unsubstituted pyrazolyl group, a substituted or unsubstituted pyridinyl group, a substituted or unsubstituted bipyridinyl group, a substituted or unsubstituted pyrazinyl group, a substituted or unsubstituted pyrimidinyl group, a substituted or unsubstituted pyridazinyl group, a substituted or unsubstituted isoindolyl group, a substituted or unsubstituted indolyl group, a substituted or unsubstituted indazolyl group, a substituted or unsubstituted purinyl group, a substituted or unsubstituted quinolinyl group, a substituted or unsubstituted benzoquinolinyl group, a substituted or unsubstituted phthalazinyl group, a substituted or unsubstituted naphthyridinyl group, a substituted or unsubstituted quinoxalinyl group, a substituted or unsubstituted quinazolinyl group, a substituted or unsubstituted cinnolinyl group, a substituted or unsubstituted carbazolyl group, a substituted or unsubstituted phenanthridinyl group, a substituted or unsubstituted acridinyl group, a substituted or unsubstituted phenanthrolinyl group, a substituted or unsubstituted phenazinyl group, a substituted or unsubstituted benzooxazolyl group, a substituted or unsubstituted benzoimidazolyl group, a substituted or unsubstituted furanyl group, a substituted or unsubstituted benzofuranyl group, a substituted or unsubstituted thiophenyl group, a substituted or unsubstituted benzothiophenyl group, a substituted or unsubstituted thiazolyl group, a substituted or unsubstituted isothiazolyl group, a substituted or unsubstituted benzothiazolyl group, a substituted or unsubstituted isoxazolyl group, a substituted or unsubstituted oxazolyl group, a substituted or unsubstituted triazolyl group, a substituted or unsubstituted tetrazolyl group, a substituted or unsubstituted oxadiazolyl group, a substituted or unsubstituted triazinyl group, a substituted or unsubstituted benzooxazolyl group, a substituted or unsubstituted dibenzopuranyl group, a substituted or unsubstituted dibenzothiophenyl group, and a substituted or unsubstituted bezocarbazolyl group, L₁, L₂, and L₃ are each independently one of a substituted or unsubstituted phenylene group, a substituted or unsubstituted pentalenylene group, a substituted or unsubstituted indenylene group, a substituted or unsubstituted naphthylene group, a substituted or unsubstituted azulenylene group, a substituted or unsubstituted heptalenylene group, a substituted or unsubstituted indacenylene group, a substituted or unsubstituted acenaphthylene group, a substituted or unsubstituted fluorenylene group, a substituted or unsubstituted phenalenylene group, a substituted or unsubstituted phenanthrenylene group, a substituted or unsubstituted anthrylene group, a substituted or unsubstituted fluoranthenylene group, a substituted or unsubstituted triphenylenylene group, a substituted or unsubstituted pyrenylene group, a substituted or unsubstituted chrysenylene group, a substituted or unsubstituted naphthacenylene group, a substituted or unsubstituted picenylene group, a substituted or unsubstituted perylenylene group, a substituted or unsubstituted pentaphenylene group, a substituted or unsubstituted hexacenylene group, a substituted or unsubstituted pyrrolylene group, a substituted or unsubstituted pyrazolylene group, a substituted or unsubstituted imidazolylene group, a substituted or unsubstituted imidazolinylene group, a substituted or unsubstituted imidazopyridinylene group, a substituted or unsubstituted imidazopyrimidinylene group, a substituted or unsubstituted pyridinylene group, a substituted or unsubstituted pyrazinylene group, a substituted or unsubstituted pyrimidinylene group, a substituted or unsubstituted indolylene group, a substituted or unsubstituted purinylene group, a substituted or unsubstituted quinolinylene group, a substituted or unsubstituted phthalazinylene group, a substituted or unsubstituted indolizinylene group, a substituted or unsubstituted naphthyridinylene group, a substituted or unsubstituted quinazolinylene group, a substituted or unsubstituted cinnolinylene group, a substituted or unsubstituted indazolylene group, a substituted or unsubstituted carbazolylene group, a substituted or unsubstituted phenazinylene group, a substituted or unsubstituted phenanthridinylene group, a substituted or unsubstituted pyranylene group, a substituted or unsubstituted chromenylene group, a substituted or unsubstituted furanylene group, a substituted or unsubstituted benzofuranylene group, a substituted or unsubstituted thiophenylene group, a substituted or unsubstituted benzothiophenylene group, a substituted or unsubstituted isothiazolylene group, a substituted or unsubstituted benzoimidazolylene group, a substituted or unsubstituted isoxazolylene group, a substituted or unsubstituted dibenzothiophenylene group, a substituted or unsubstituted dibenzopuranylene group, a substituted or unsubstituted triazinylene group, and a substituted or unsubstituted oxadiazolylene group, and a, b, and c are each independently an integers of 0 to 1.

In Formulae 2 and 3, when a is 0, -(L₁)ₐ- indicates a single bond, when b is 0, -(L₂)_{b}- indicates a single bond, and when c is 0, -(L₃)_{c}- indicates a single bond.

The compounds represented by Formulae 2 and 3 have a HOMO energy level in a range from −5.2 eV to −6.1 eV and a LUMO energy level in a range from −2.5 eV to −3.2 eV. A compound represented by Formula 2 includes a benzimidazole group in a molecular structure of the compound, and a compound represented by Formula 3 includes a pyridyl group in a molecular structure of the compound, and thus the compounds have a relatively excellent electron mobility.

In the electron control layer 171 or 271 including at least one of the compounds represented by Formulae 2 and 3, injection and transportation of electrons may be fastened at a high luminance region, and injection and transportation of electrons may be slowed down at a low luminance region.

For example, the electron control material may include at least one of Compounds 1 and 2 below:

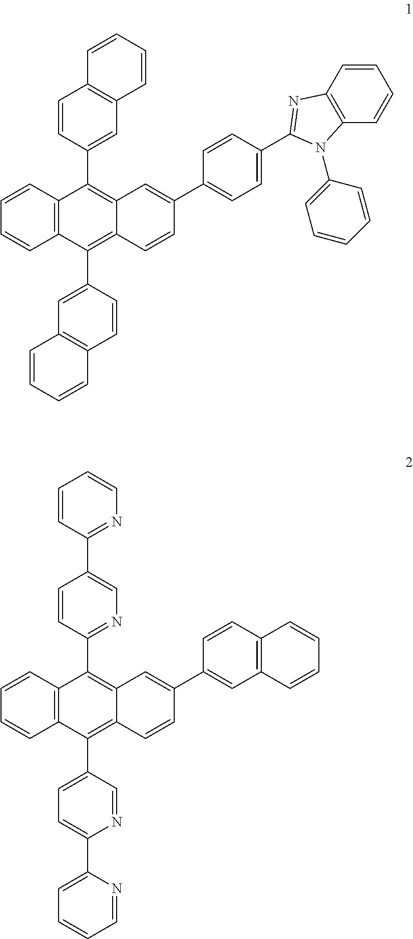 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc(-c3c4ccccc4c(-c4ccc(-c5ccccn5)nc4)c4ccc(-c5ccc6ccccc6c5)cc34)nc2)nc1]

In this regard, the electron control layer 171 or 271 may include Compound 1, Compound 2, or a mixture of Compounds 1 and 2 with a content of about 30 wt % to 100 wt % based on a total weight of the electron control layer 171 or 271.

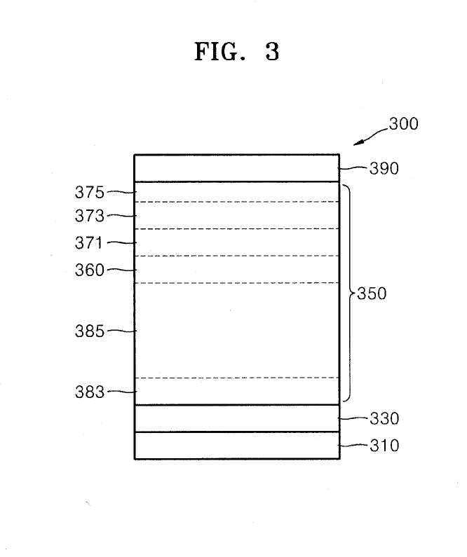

FIG. 3 is a schematic cross-sectional view of an OLED 300 having a structure of a substrate 310/a first electrode 330/a hole injection layer 383/a hole transport layer 385/an emission layer 360/an electron control layer 371/an electron transport layer 373/an electron injection layer 375/a second electrode 390 according to an embodiment. Hereinafter, according to an embodiment, a structure of the OLED 300 and a method of manufacturing the OLED 300 will be described in detail.

The substrate 310, which may be any substrate that is used in a conventional OLED, may be a glass substrate or a transparent plastic substrate with excellent mechanical strength, thermal stability, transparency, surface smoothness, ease of handling, and waterproofness.

The first electrode 330 may be formed by depositing or sputtering a material that is used to form the first electrode 330 on the substrate 310. If the first electrode 330 is an anode, a material used for forming a first electrode may be a high work-function material so as to facilitate hole injection. The first electrode 330 may be a reflective electrode or a transmission electrode. As the material for forming a first electrode, transparent and conductive materials such as ITO, IZO, SnO₂, and ZnO may be used. The first electrode 330 may be formed as a reflective electrode using Mg, Al, Al—Li, Ca, Ag-ITO, Mg—In, Mg—Ag, or the like. The first electrode 330 may have a structure of a single layer or multiple layers of 2 or more layers. For example, the first electrode 330 may have a 3-layered structure of ITO/Ag/ITO, but is not limited thereto.

An organic layer 350 is formed on the first electrode 330. The organic layer 350 may include the hole injection layer 383, the hole transport layer 385, a buffer layer (not shown), the emission layer 360, the electron control layer 371, the electron transport layer 373, and the electron injection layer 375.

The hole injection layer 383 may be formed on the first electrode 330 by using a vacuum deposition, a spin coating, a casting, a Langmuir-Blodgett (LB) method, or the like. When the hole injection layer 383 is formed by using a vacuum deposition, the deposition conditions may vary according to a compound that is used as a material for forming a hole injection layer, and the structure and thermal properties of the hole injection layer 383 to be formed. In general, however, conditions for the vacuum deposition may be include a deposition temperature in a range of about 100 to about 500° C., a pressure in a range of about 10⁻⁸ to about 10⁻³ torr, and a deposition rate in a range of about 0.01 to about 100 Å/sec. When the hole injection layer 383 is formed by using a spin coating, the coating conditions may vary according to a compound that is used as a material for forming a hole injection layer, and the structure and thermal properties of the hole injection layer 383 to be formed. In general, however, the coating rate may be from about 2000 to about 5000 rpm, and a temperature for heat treatment which is performed to remove a solvent after coating may be from about 80 to 200° C.

As the material for forming a hole injection layer, a compound represented by Formula 6 below may be used, but is not limited thereto:

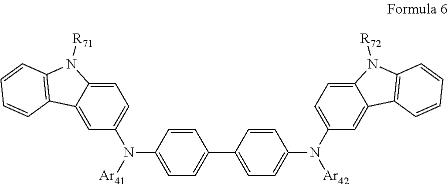

In Formula 6, Ar₄₁ and Ar₄₂ are each independently one of a substituted or unsubstituted C₆-C₃₀ arylene group and a substituted or unsubstituted C₂-C₃₀ heteroarylene group, R₇₁ and R₇₂ are each independently one of a hydrogen, a deuterium, a halogen, a hydroxy group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₆-C₃₀ aryl group, a substituted or unsubstituted C₆-C₃₀ aryloxy group, and a substituted or unsubstituted C₆-C₃₀ arylthio group.

As the material for forming a hole injection layer, for example, the compound represented by Formula 6 above or a mixture of the compound represented by Formula 6 above and a commonly known material for forming a hole injection layer may be used.

The compound represented by Formula 6 above may be one of Compounds 301 to 308 below, but is not limited thereto.

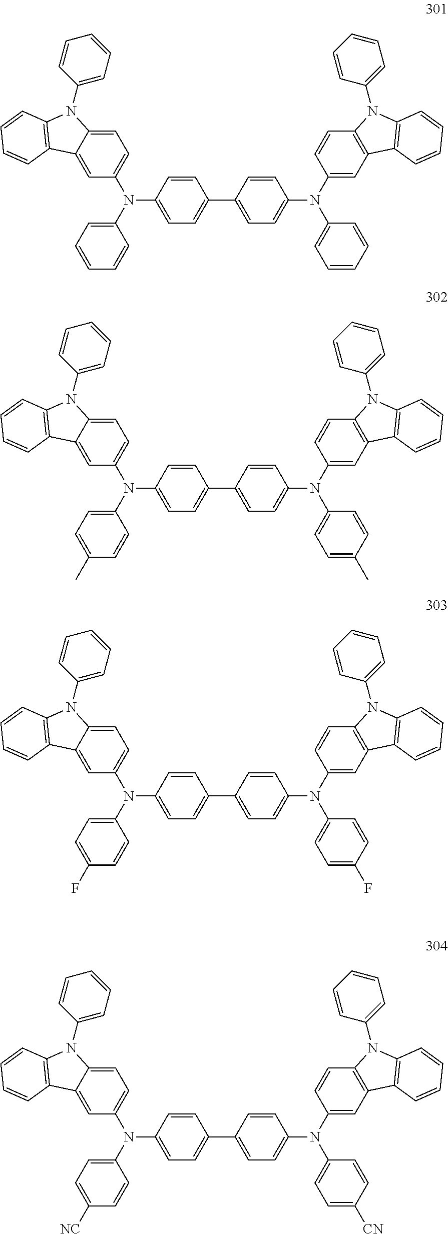 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

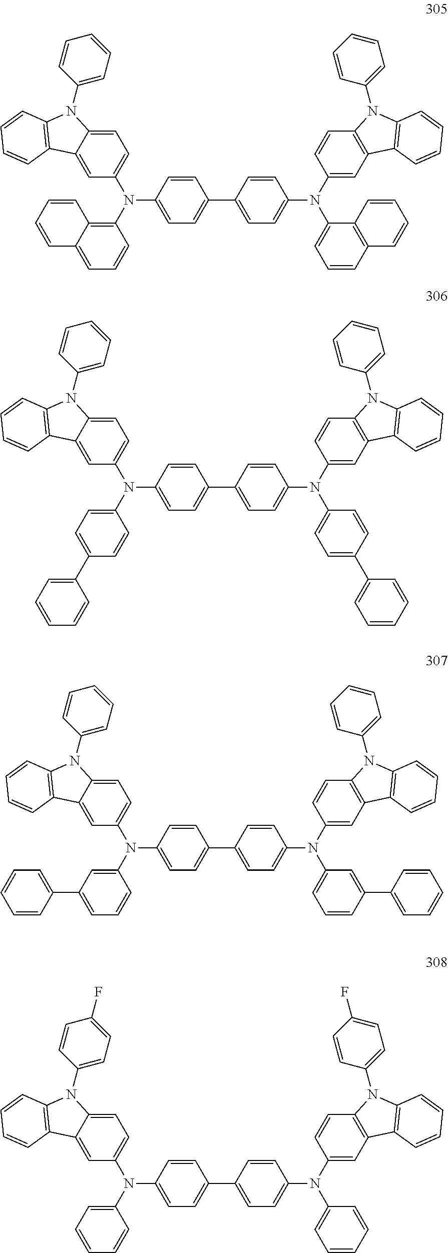 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

An example of the commonly known material for forming a hole injection layer may be N,N′-diphenyl-N,N′-bis-[4-(phenyl-m-tolyl-amino)-phenyl]-biphenyl-4,4′-diamine (DNTPD), a phthalocyanine compound such as copperphthalocyanine, 4,4′,4″-tris (3-methylphenylphenylamino)triphenylamine (m-MTDATA), N,N′-di(1-naphthyl)-N,N′-diphenylbenzidine (NPB), TDATA, 2-TNATA, Polyaniline/Dodecylbenzenesulfonic acid (Pani/DBSA), Poly(3,4-ethylenedioxythiophene)/Poly(4-styrenesulfonate (PEDOT/PSS), Polyaniline/Camphor sulfonicacid (Pani/CSA), or Polyaniline)/Poly(4-styrenesulfonate) (PANI/PSS), but is not limited thereto.

A thickness of the hole injection layer 383 may be in a range of about 100 Å to about 10000 Å, for example, about 100 Å to about 1000 Å. If the thickness of the hole injection layer 383 is within the range described above, an excellent hole injecting ability may be obtained without a substantial increase of driving voltage.

Next, the hole transport layer 385 may be formed on the hole injection layer 383 by using a vacuum deposition, a spin coating, a casting, a LB method, or the like. When the hole transport layer 385 is formed by a vacuum deposition or a spin coating, although the conditions for the deposition and coating may vary according to the material that is used for forming a hole transport layer, generally the conditions for deposition and coating may be similar to those for the formation of the hole injection layer 383.

For a material for forming a hole transport layer, a compound represented by Formula 6 below may be used, but is not limited thereto:

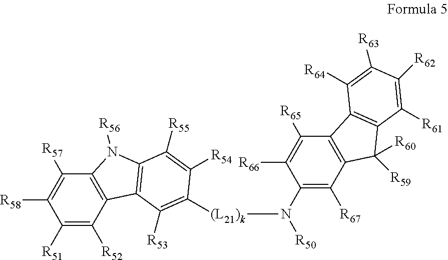

In Formula 5, R₅₀ is one of a substituted or unsubstituted phenyl group, a substituted or unsubstituted naphthyl group, a substituted or unsubstituted anthryl group, a substituted or unsubstituted biphenyl group, and a substituted or unsubstituted pyridyl group; L₂₁ is one of a substituted or unsubstituted C₁-C₃₀ alkylene group, a substituted or unsubstituted C₂-C₃₀ alkenylene group, a substituted or unsubstituted C₆-C₃₀ arylene group, and a substituted or unsubstituted C₂-C₃₀ heteroarylene group; R₅₁ to R₆₇ are each independently one of a hydrogen, a deuterium, a halogen, a hydroxy group, a cyano group, a nitro group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthiol group, a substituted or unsubstituted C₃-C₃₀ cycloalkyl group, a substituted or unsubstituted C₃-C₃₀ cycloalkenyl group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₂-C₃₀ heteroaryl group, and a group represented by —N(Q₁₁)(Q₁₂); and k is one of integers of 0 to 3.

In —N(Q₁₁)(Q₁₂), Q₁₁ and Q₁₂ are each independently one of a hydrogen, a deuterium, a halogen, a hydroxy group, a cyano group, an amino group, a nitro group, a carboxyl group, a C₁-C₃₀ alkyl group, a C₂-C₃₀ alkenyl group, a C₂-C₃₀ alkynyl group, a C₁-C₃₀ alkoxy group, a C₁-C₃₀ alkylthiol group, a C₃-C₃₀ cycloalkyl group, a C₃-C₃₀ cycloalkenyl group, a C₆-C₃₀ aryl group, a C₆-C₃₀ aryloxy group, a C₆-C₃₀ arylthio group, and a C₂-C₃₀ heteroaryl group.

In Formula 5, when k is 0, -(L₂₁)ₖ— indicates a single bond, and when k is 2 or greater, a plurality of L₂₁ may be identical to or different from each other.

As the material for forming a hole transport layer, for example, the compound represented by Formula 5 above or a mixture of the compound represented by Formula 6 above and a commonly known material for forming a hole transport layer may be used.

The compound represented by Formula 5 above may be one of Compounds 309 to 320 below, but is not limited thereto:

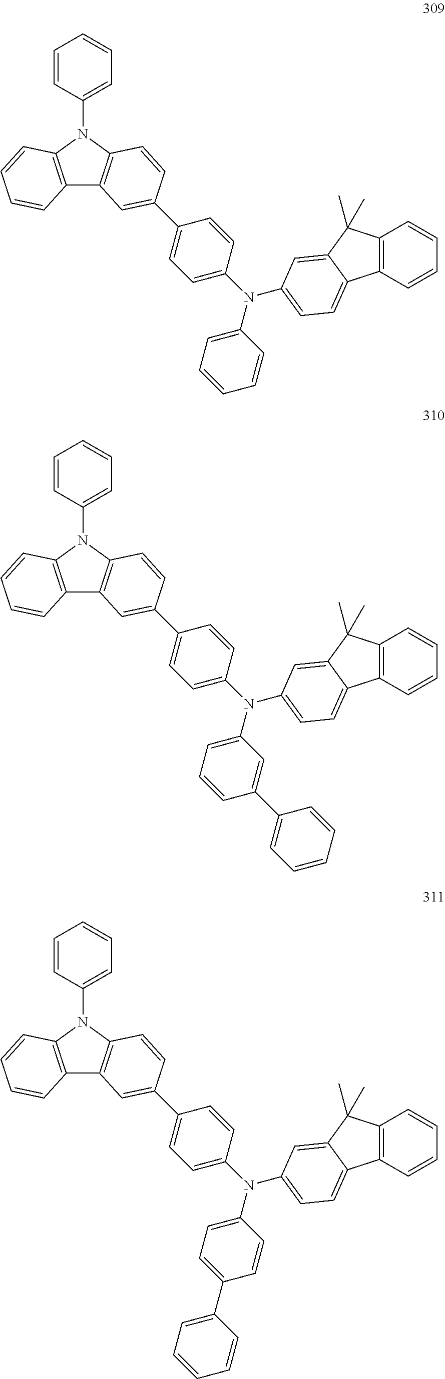 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

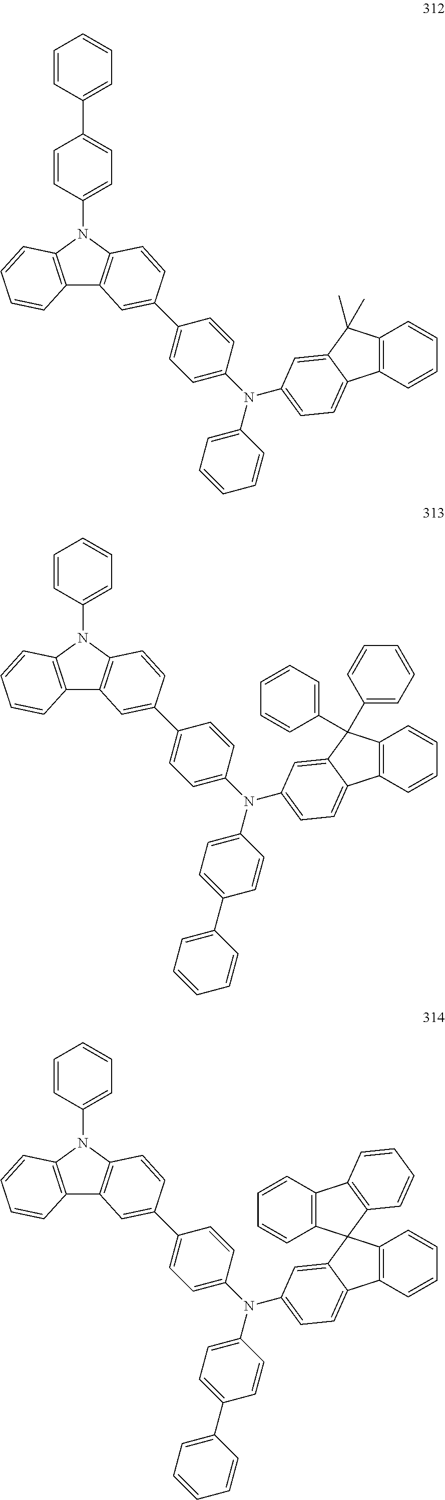 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

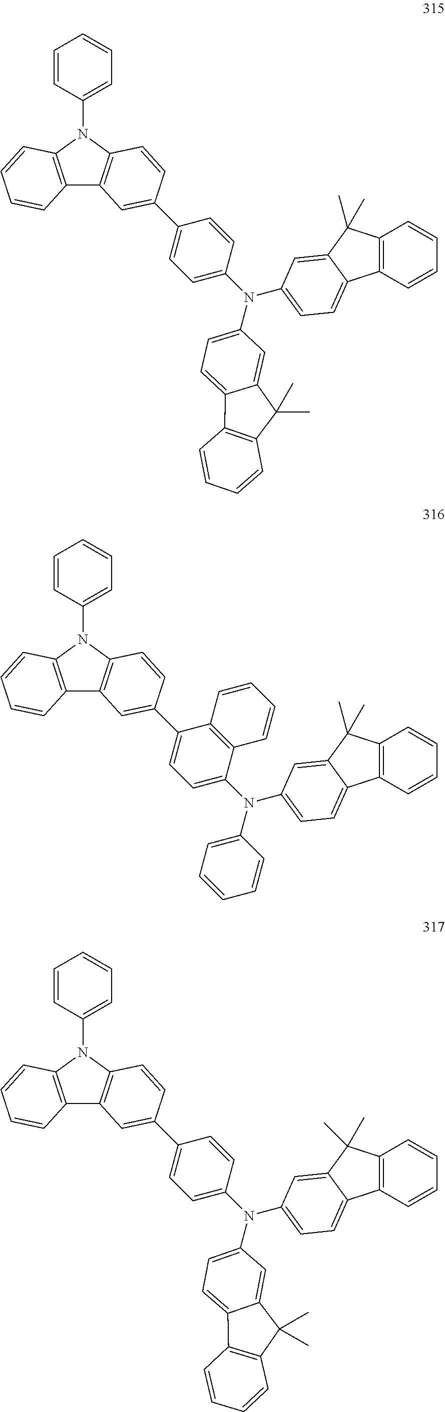 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

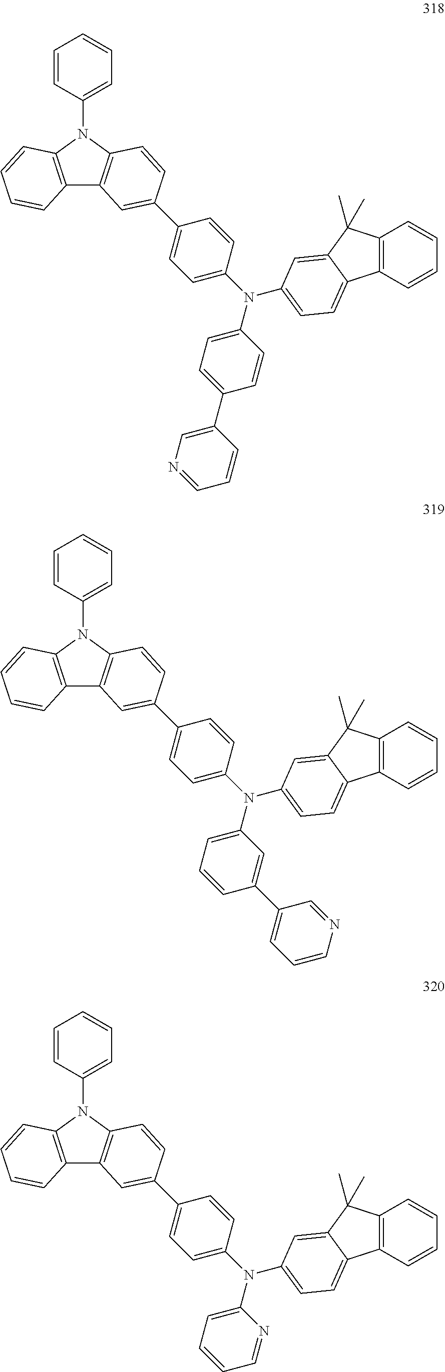 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

An example of the commonly known material for forming a hole transport layer may be a carbazole derivative such as N-phenylcarbazole, polyvinylcarbazole, or the like, N,N′-bis(3-methylphenyl)-N,N-diphenyl-[1,1-biphenyl]-4,4′-diamine (TPD), 4,4′,4″-tris(N-carbazolyl)triphenylamine (TCTA), N,N′-di(1-naphthyl)-N,N′-diphenylbenzidine (NPB), or the like, but is not limited thereto. A thickness of the hole transport layer 385 may be in a range from about 50 Å to about 2000 Å, for example, from about 100 Å to about 1500 Å. If the thickness of the hole transport layer 385 is within the range described above, an excellent hole transportation ability may be obtained without a substantial increase of driving voltage.

On the first electrode 330, one of the hole injection layer 383 and the hole transport layer 385 may be formed and the other may be omitted, or at least one of the hole injection layer 383 and the hole transport layer 385 may be formed in a form of multiple layers. Alternatively, a functional layer (not shown) having hole injection and transport ability may be disposed on the first electrode 330 instead of a hole injection layer and a hole transport layer. The functional layer having hole injection and transport ability may be formed with at least one of the compound represented by Formula 5, a mixture of the compound represented by Formula 5 and the material for forming a hole transport layer, the compound represented by Formula 6, and a mixture of the compound represented by Formula 6 and the material for forming a hole injection layer. Also, a thickness of the functional layer may be in a range from about 500 Å to about 10000 Å, for example, from about 100 Å to about 1000 Å. If the thickness of the functional layer is within the range described above, an excellent hole injection and transportation ability may be obtained without a substantial increase of driving voltage.

The emission layer 360 may be formed on the hole transport layer 385 or the functional layer (not shown) having hole injection and transport ability by using a vacuum deposition, a spin coating, a casting, a LB method, or the like. When the emission layer 360 is formed by using a vacuum deposition and a spin coating, although the conditions for the deposition and coating may vary according to the compound that is used for forming the emission layer 360, generally the conditions for deposition and coating may be similar to those for the formation of the hole injection layer 383.

As a host material of the emission layer 360, a bipolar compound having both of a hole transport unit and an electron transport unit. The hole transport unit refers to a unit including a functional group with an excellent hole transporting ability which may be, for example, a unit including a fluorine derivative, a unit including a carbazole derivative, a unit including a dibenzothiophene derivative, or a unit including a dibenzofuran derivative. The electron transport unit refers to a unit including a functional group with an excellent electron transporting ability which may be, for example, a unit including a pyridine derivative, a unit including a pyrimidine derivative, or a unit including a triazine derivative. If the bipolar compound having both of the hole transport unit and the electron transport unit is used as the host material, a reduction of a luminous efficiency may well occur as electrons and holes in the host material at a low luminance region are unbalanced due to the electron control layer 371.

Alternatively, as the host material of the emission layer 360, a mixture of a bipolar compound having both of a hole transport unit and an electron transport unit and a compound having at least a hole transport unit. If the compound having at least a hole transport unit is further added to the bipolar compound as the host material, a reduction of a luminous efficiency may further well occur as electrons and holes in the host material at a low luminance region are further unbalanced since hole characteristics of the host material is further increased. A mixture ratio of the bipolar compound and the compound having at least a hole transport unit may be from about 1:1 to about 1:9. If the mixture ratio of the bipolar compound and the compound having at least a hole transport unit is in the range above, imbalance of electrons and holes in the host material may be further increased.

For example, the host material may be one of Compounds 501 to 509 below:

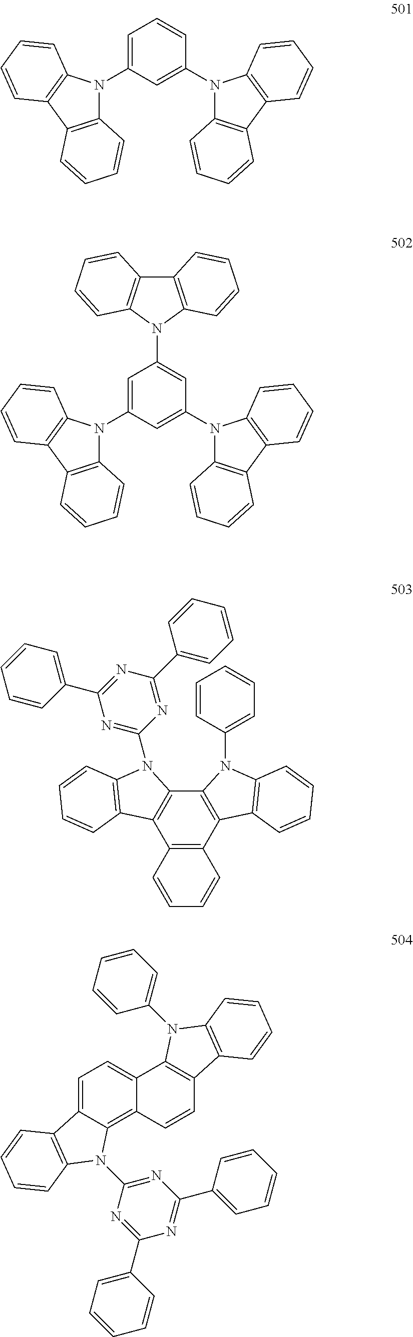 [SMILES: c1cc(-n2c3ccccc3c3ccccc32)cc(-n2c3ccccc3c3ccccc32)c1 ; c1ccc2c(c1)c1ccccc1n2-c1cc(-n2c3ccccc3c3ccccc32)cc(-n2c3ccccc3c3ccccc32)c1 ; c1ccc(-c2nc(-c3ccccc3)nc(-n3c4ccccc4c4c5ccccc5c5c6ccccc6n(-c6ccccc6)c5c43)n2)cc1 ; c1ccc(-c2nc(-c3ccccc3)nc(-n3c4ccccc4c4ccc5c(ccc6c7ccccc7n(-c7ccccc7)c65)c43)n2)cc1]

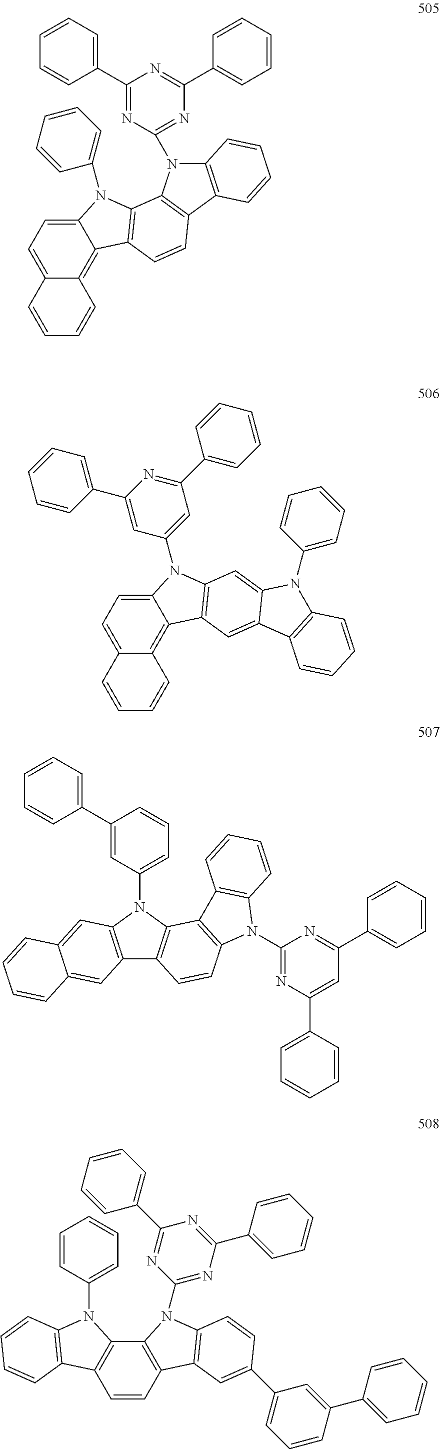 [SMILES: c1ccc(-c2nc(-c3ccccc3)nc(-n3c4ccccc4c4ccc5c6c7ccccc7ccc6n(-c6ccccc6)c5c43)n2)cc1 ; c1ccc(-c2cc(-n3c4cc5c(cc4c4c6ccccc6ccc43)c3ccccc3n5-c3ccccc3)cc(-c3ccccc3)n2)cc1 ; c1ccc(-c2cccc(-n3c4cc5ccccc5cc4c4ccc5c(c6ccccc6n5-c5nc(-c6ccccc6)cc(-c6ccccc6)n5)c43)c2)cc1 ; c1ccc(-c2cccc(-c3ccc4c(c3)c3ccc5c6ccccc6n(-c6ccccc6)c5c3n4-c3nc(-c4ccccc4)nc(-c4ccccc4)n3)c2)cc1]

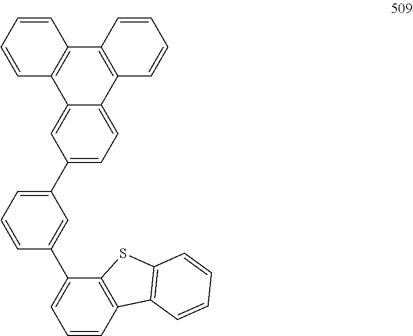 [SMILES: c1cc(-c2ccc3c4ccccc4c4ccccc4c3c2)cc(-c2cccc3c2sc2ccccc23)c1]

The emission layer 360 may be patterned to a red emission layer, a green emission layer, or a blue emission layer. At least one of a red emission layer, a green emission layer, and a blue emission layer may include a dopant below (ppy=phenylpyridine).

For example, compounds below may be used as a blue dopant, but is not limited thereto:

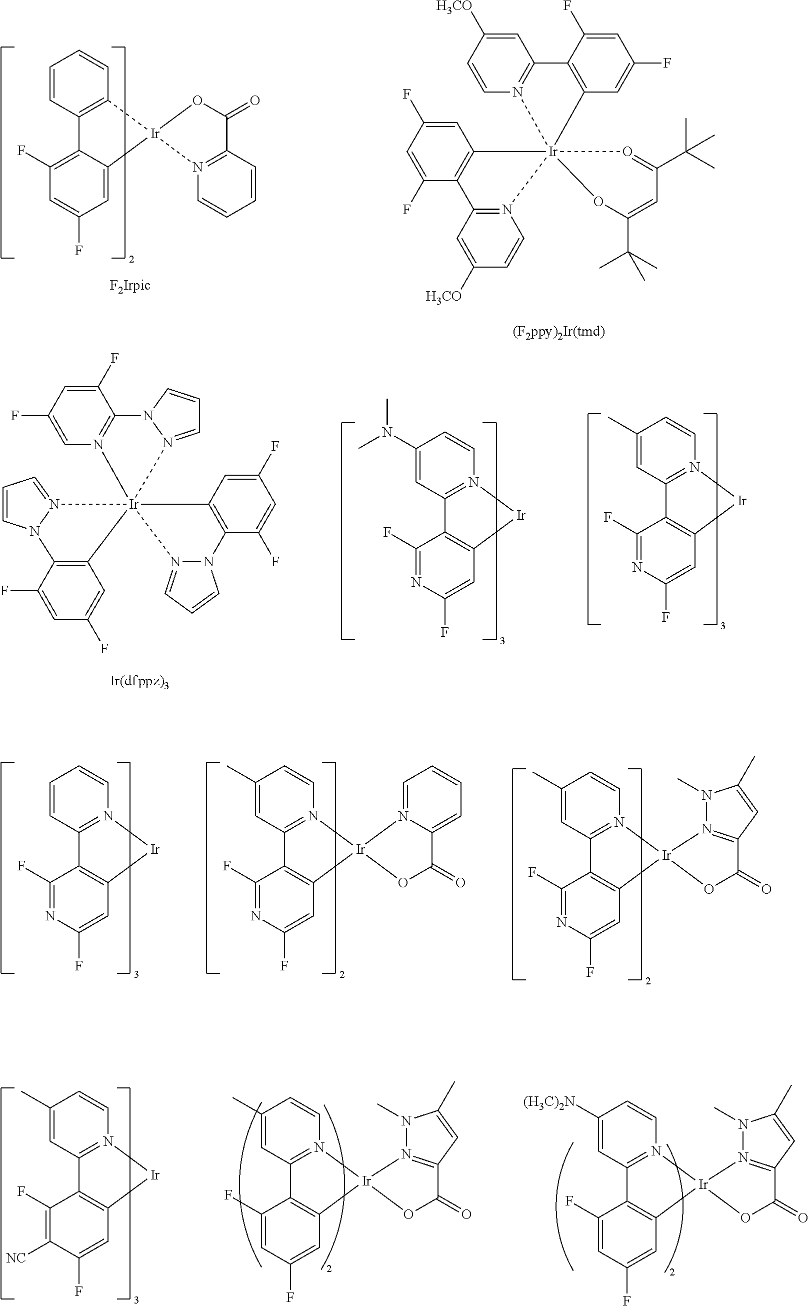

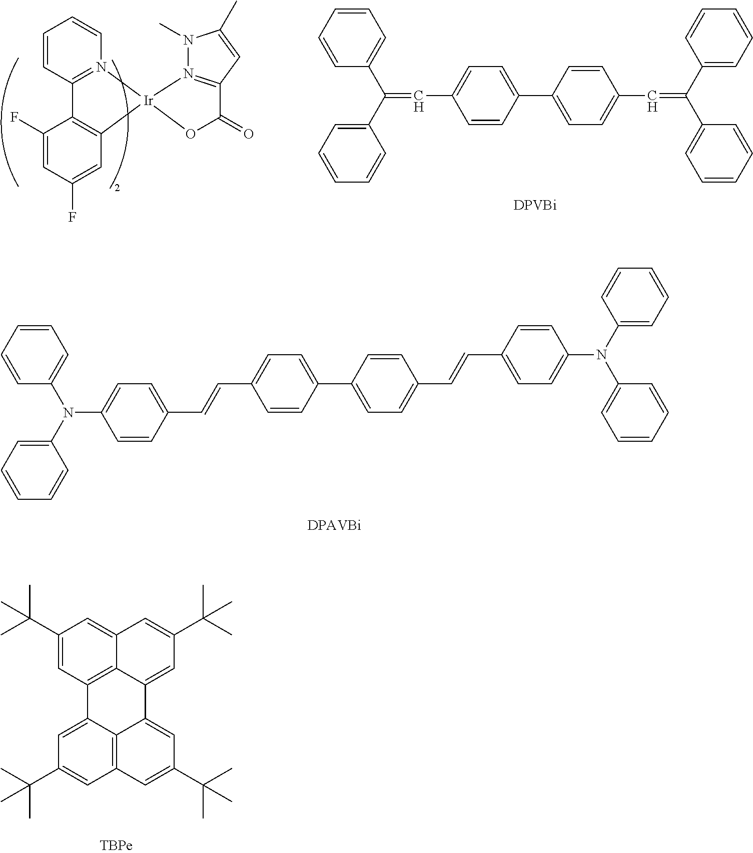

For example, compounds below may be used as a red dopant, but the disclosure is not limited thereto:

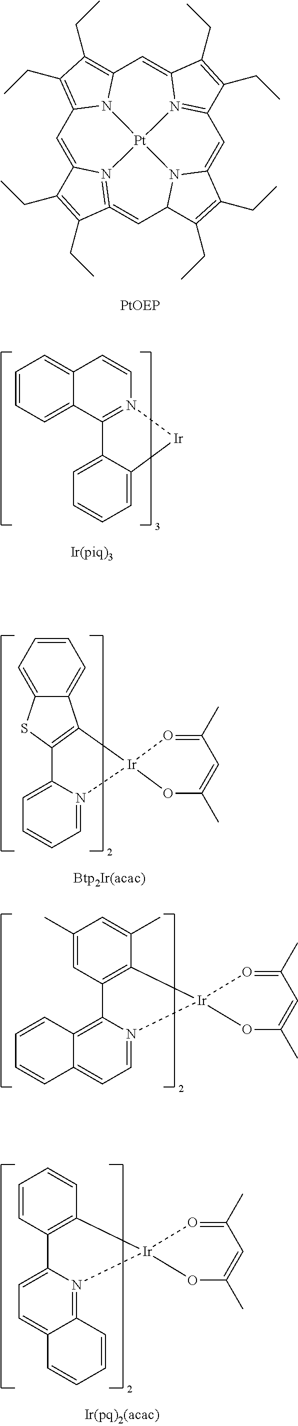

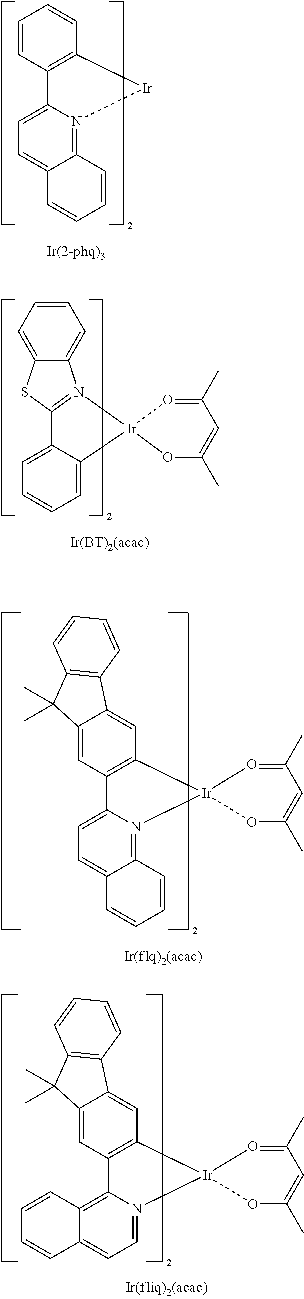

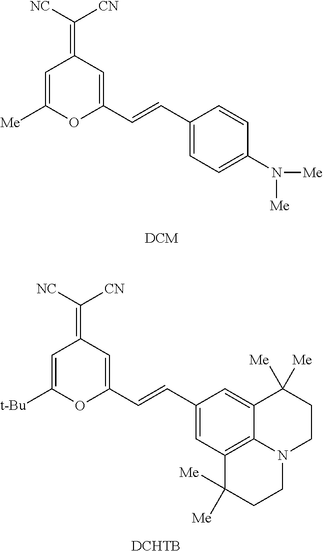 [SMILES: CC1=CC(=C(C#N)C#N)C=C(/C=C/c2ccc(N(C)C)cc2)O1 ; CC(C)(C)C1=CC(=C(C#N)C#N)C=C(/C=C/c2cc3c4c(c2)C(C)(C)CCN4CCC3(C)C)O1 ; "DCHTB"]

For example, compounds below may be used as a green dopant, but the disclosure is not limited thereto:

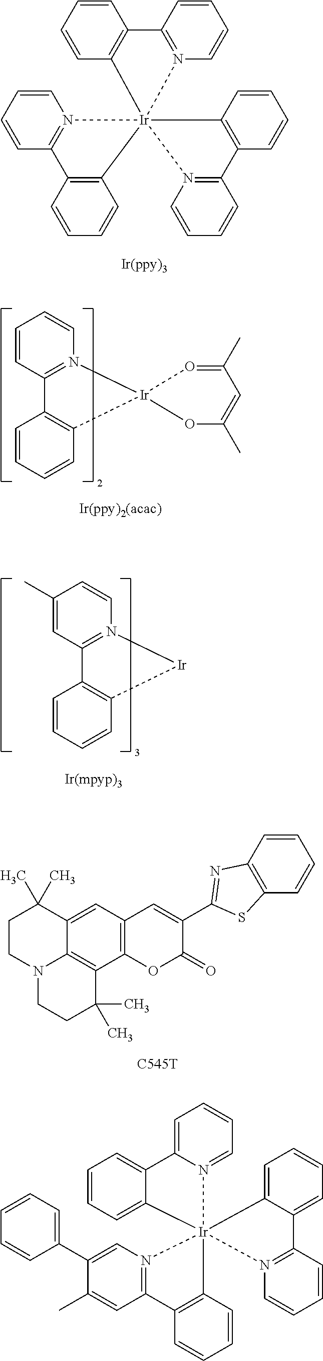

For example, a dopant that may be included in the emission layer 360 may be Pt-complexes below, but is not limited thereto:

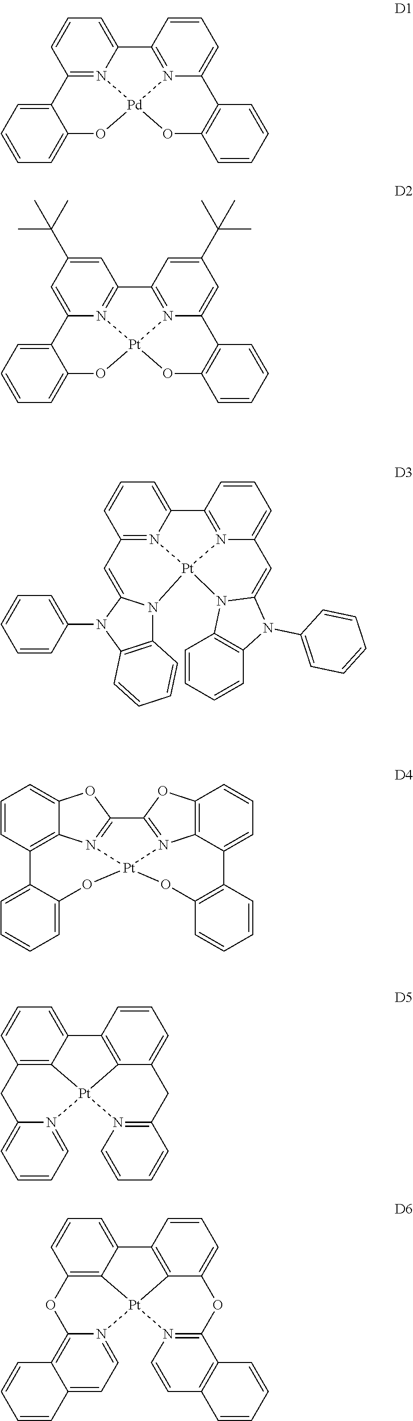

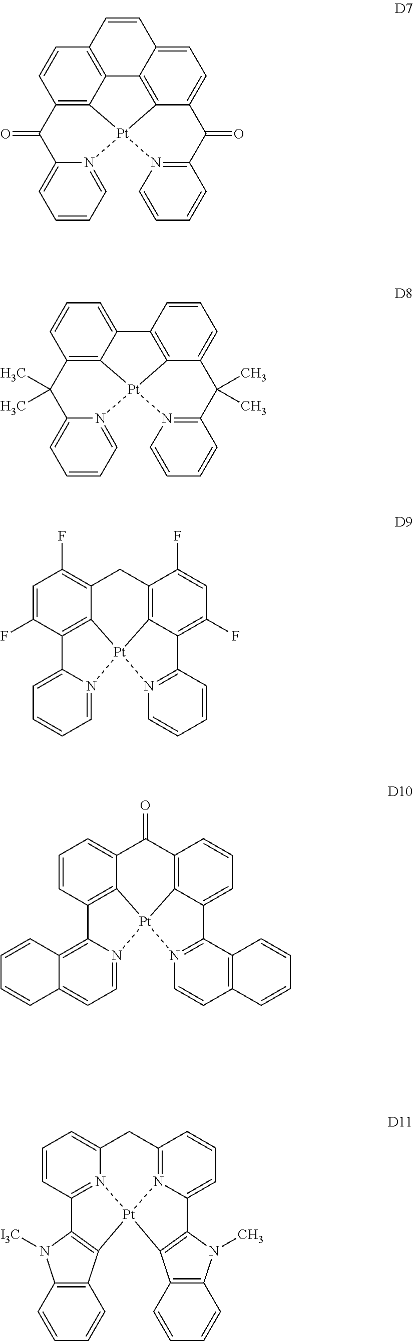

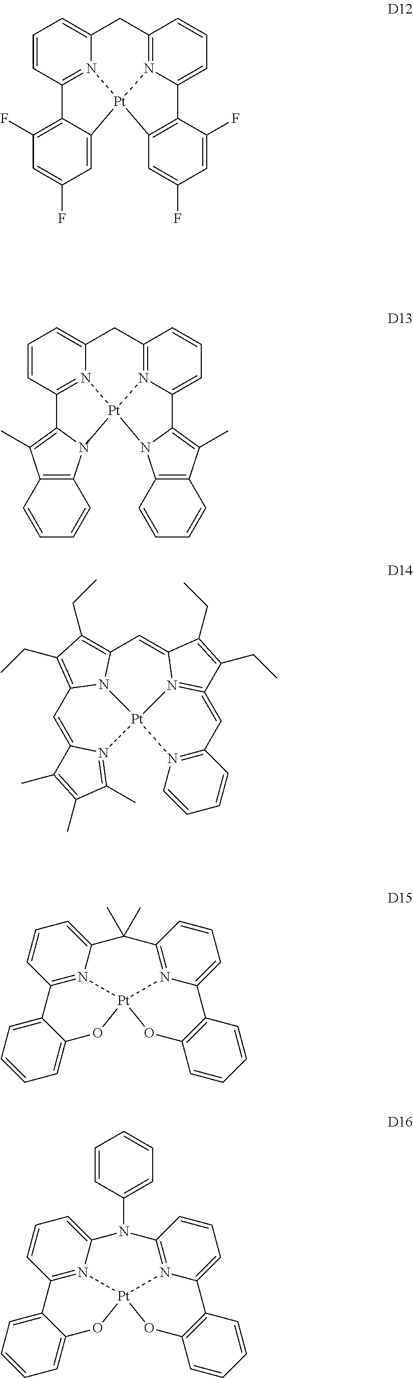

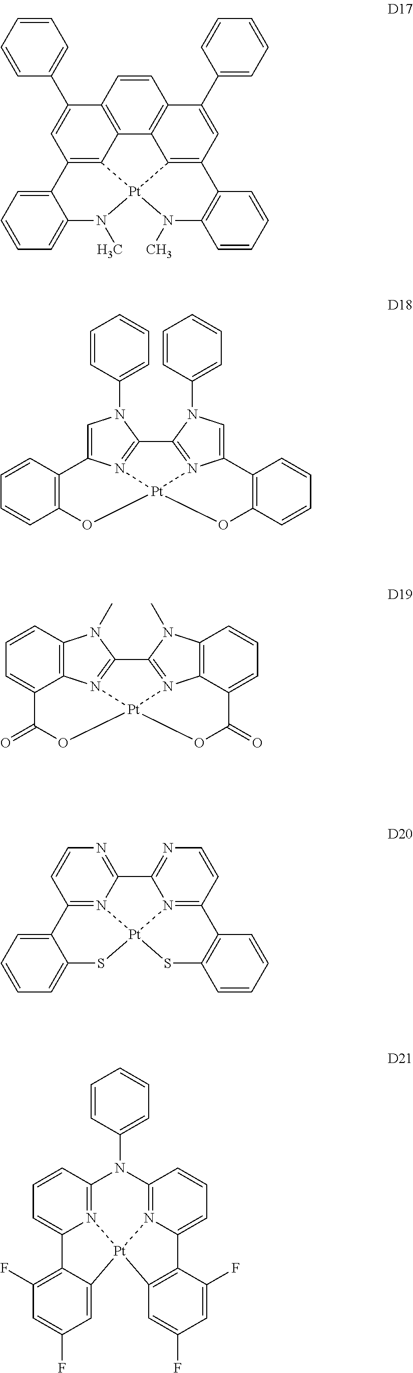

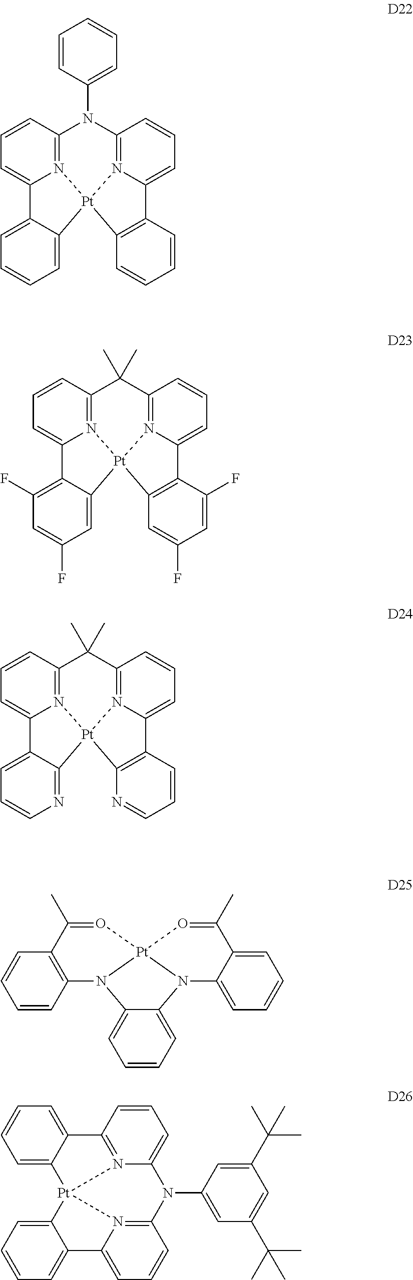

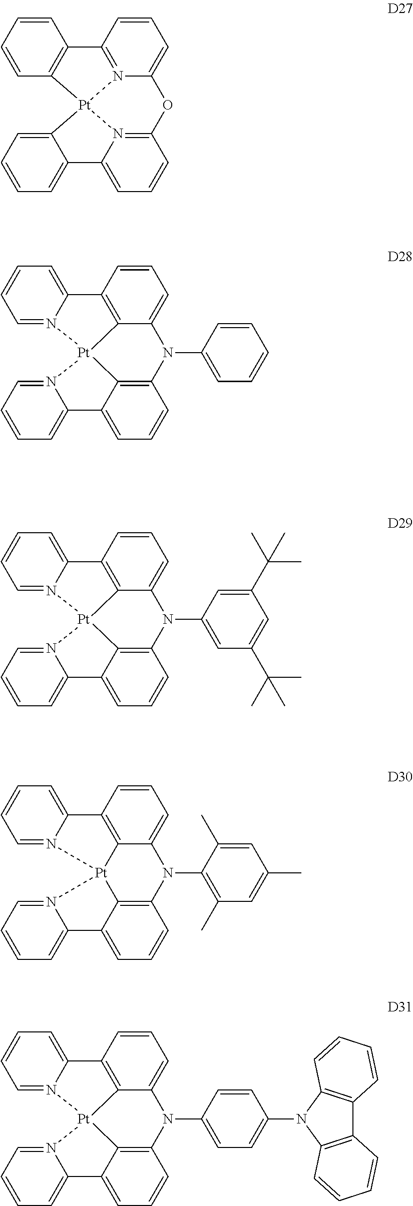

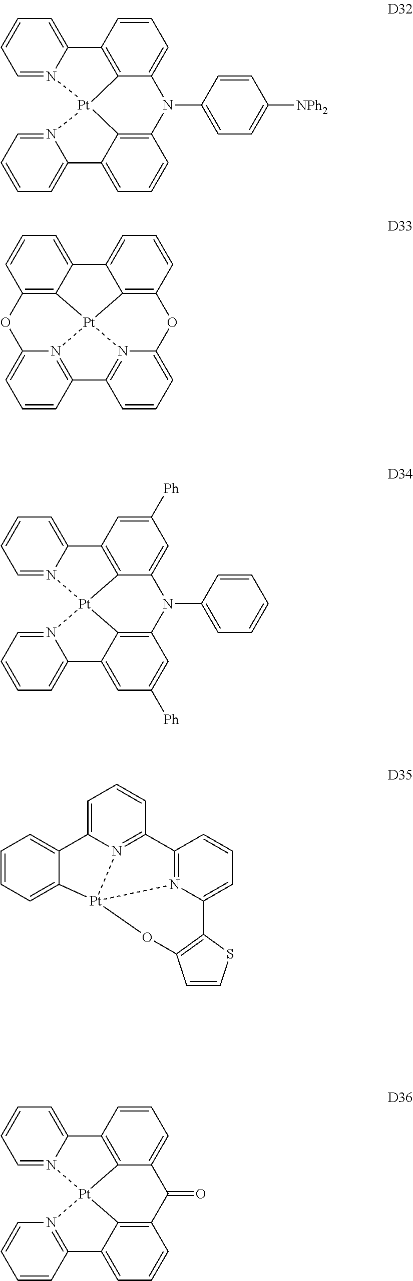

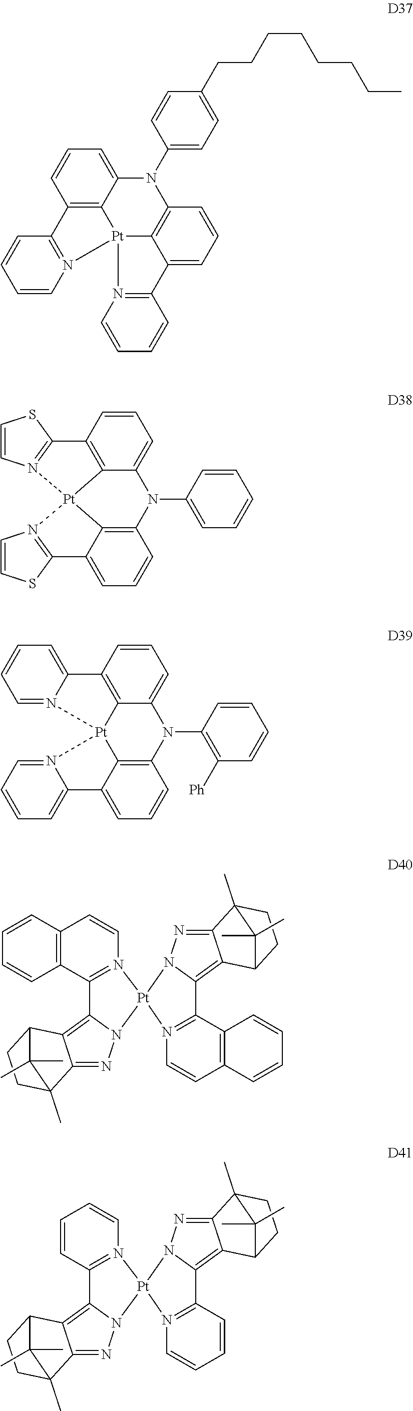

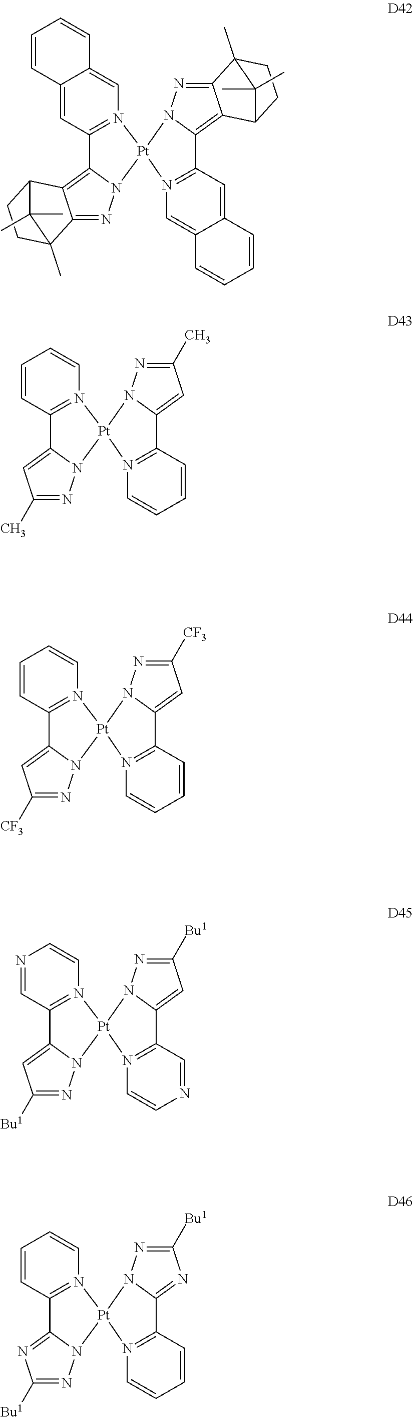

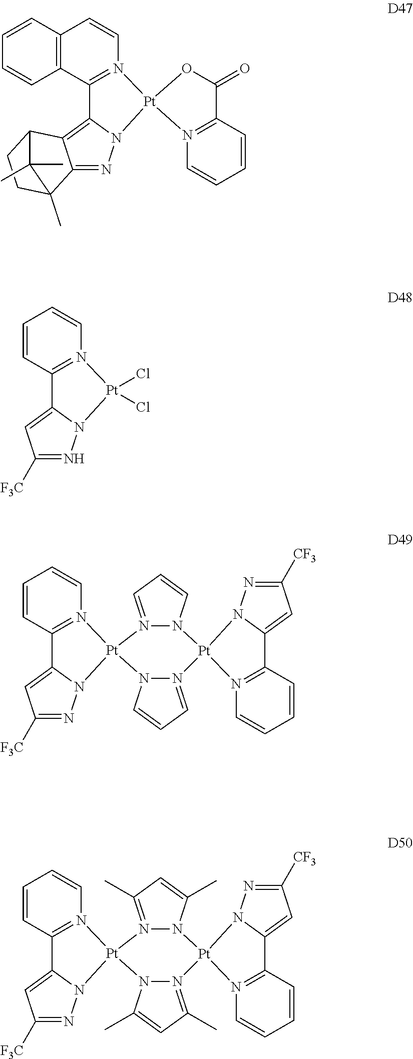

Also, a dopant that may be included in the emission layer 360 may be one of Os-complexes below, but is not limited thereto:

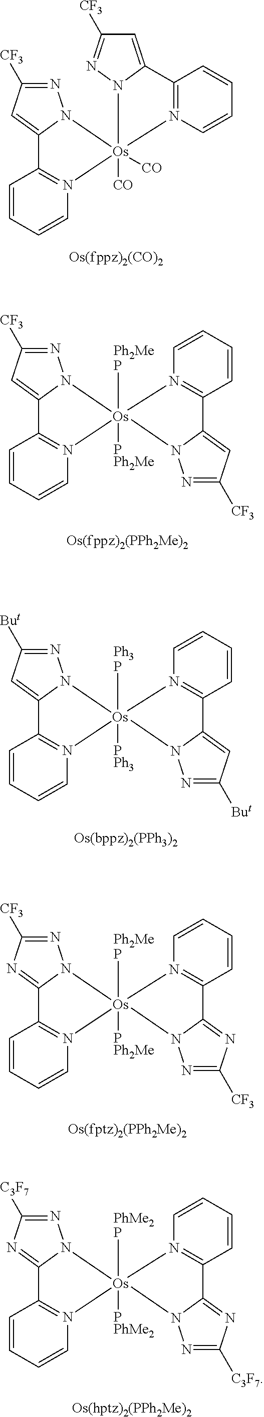

If the emission layer 360 includes a host material and a dopant material, a content of the dopant material may be selected in a range from about 0.01 to about 25 parts by weight based on about 100 parts by weight of the host material, but is not limited thereto.

A thickness of the emission layer may be in a range from about 100 Å to about 1000 Å, for example, from about 200 Å to about 600 Å. For example, if the thickness of the emission layer 360 is in the range above, an excellent light-emitting ability may be obtained without a substantial increase of driving voltage.

Next, the electron control layer 371 may be formed on the emission layer 360 by using a vacuum deposition, a spin coating, a casting, or the like. When the electron control layer 371 is formed by using a vacuum deposition and a spin coating, although the conditions for the deposition and coating may vary according to the compound that is used for forming the electron control layer 371, generally the conditions for deposition and coating may be similar to those for the formation of the hole injection layer 383. As a material for forming the electron control layer 371, the electron control material satisfying the molecular orbital energy level described above may be used. A thickness of the electron control layer 371 may be in a range from 50 Å to 450 Å, and a thickness ratio of the electron transport layer 373 and the electron control layer 371 may be selected in a range from 5:1 to 5:10.

The electron transport layer 373 is formed on the electron control layer 371 by using a vacuum deposition, a spin coating, a casting, or the like. When the electron transport layer 373 is formed by using a vacuum deposition and a spin coating, although conditions for the deposition and coating may vary according to the compound that is used for forming the electron transport layer 373, generally the conditions for deposition and coating may be similar to those for the formation of the hole injection layer 383. As a material for forming an electron transport layer, a compound represented by Formula 4 below which serves to stably transport the electrons injected from an electron injection electrode (cathode) may be used, but is not limited thereto:

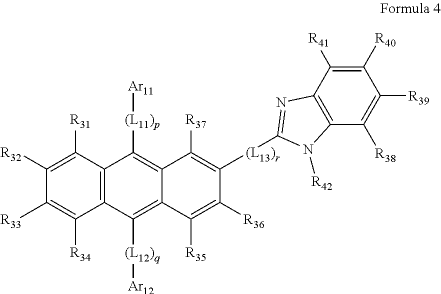

In Formula 4, R₃₁ to R₄₂ are each independently one of a hydrogen, a deuterium, a substituted or unsubstituted methyl group, a substituted or unsubstituted ethyl group, a substituted or unsubstituted propyl group, a substituted or unsubstituted butyl group, a substituted or unsubstituted phenyl group, a substituted or unsubstituted biphenyl group, a substituted or unsubstituted naphthyl group, a substituted or unsubstituted anthryl, a substituted or unsubstituted phenanthrenyl, a substituted or unsubstituted pyrenyl group, Ar₁₁ and Ar₁₂ are each independently one of a substituted or unsubstituted phenyl group, a substituted or unsubstituted pentalenyl group, a substituted or unsubstituted indenyl group, a substituted or unsubstituted naphtyl group, a substituted or unsubstituted azulenyl group, a substituted or unsubstituted heptalenyl group, a substituted or unsubstituted indacenyl group, a substituted or unsubstituted acenaphtyl group, a substituted or unsubstituted fluorenyl group, a substituted or unsubstituted spirofluorenyl group, a substituted or unsubstituted phenalenyl group, a substituted or unsubstituted phenanthrenyl group, a substituted or unsubstituted anthryl group, a substituted or unsubstituted fluoranthenyl group, a substituted or unsubstituted triphenylenyl group, a substituted or unsubstituted pyrenyl group, a substituted or unsubstituted chrysenyl group, a substituted or unsubstituted naphthacenyl group, a substituted or unsubstituted picenyl group, a substituted or unsubstituted perylenyl group, a substituted or unsubstituted pentaphenyl group, a substituted or unsubstituted hexacenyl group, a substituted or unsubstituted pyrrolyl group, a substituted or unsubstituted imidazolyl group, a substituted or unsubstituted pyrazolyl group, a substituted or unsubstituted pyridinyl group, a substituted or unsubstituted bipyridinyl group, a substituted or unsubstituted pyrazinyl group, a substituted or unsubstituted pyrimidinyl group, a substituted or unsubstituted pyridazinyl group, a substituted or unsubstituted isoindolyl group, a substituted or unsubstituted indolyl group, a substituted or unsubstituted indazolyl group, a substituted or unsubstituted purinyl group, a substituted or unsubstituted quinolinyl group, a substituted or unsubstituted benzoquinolinyl group, a substituted or unsubstituted phthalazinyl group, a substituted or unsubstituted naphthyridinyl group, a substituted or unsubstituted quinoxalinyl group, a substituted or unsubstituted quinazolinyl group, a substituted or unsubstituted cinnolinyl group, a substituted or unsubstituted carbazolyl group, a substituted or unsubstituted phenanthridinyl group, a substituted or unsubstituted acridinyl group, a substituted or unsubstituted phenanthrolinyl group, a substituted or unsubstituted phenazinyl group, a substituted or unsubstituted benzooxazolyl group, a substituted or unsubstituted benzoimidazolyl group, a substituted or unsubstituted furanyl group, a substituted or unsubstituted benzofuranyl group, a substituted or unsubstituted thiophenyl group, a substituted or unsubstituted benzothiophenyl group, a substituted or unsubstituted thiazolyl group, a substituted or unsubstituted isothiazolyl group, a substituted or unsubstituted benzothiazolyl group, a substituted or unsubstituted isoxazolyl group, a substituted or unsubstituted oxazolyl group, a substituted or unsubstituted triazolyl group, a substituted or unsubstituted tetrazolyl group, a substituted or unsubstituted oxadiazolyl group, a substituted or unsubstituted triazinyl group, a substituted or unsubstituted benzooxazolyl group, a substituted or unsubstituted dibenzopuranyl group, a substituted or unsubstituted dibenzothiophenyl group, and a substituted or unsubstituted bezocarbazolyl group, L₁₁, L₁₂ and L₁₃ are each independently one of a substituted or unsubstituted phenylene group, a substituted or unsubstituted pentalenylene group, a substituted or unsubstituted indenylene group, a substituted or unsubstituted naphthylene group, a substituted or unsubstituted azulenylene group, a substituted or unsubstituted heptalenylene group, a substituted or unsubstituted indacenylene group, a substituted or unsubstituted acenaphthylene group, a substituted or unsubstituted fluorenylene group, a substituted or unsubstituted phenalenylene group, a substituted or unsubstituted phenanthrenylene group, a substituted or unsubstituted anthrylene group, a substituted or unsubstituted fluoranthenylene group, a substituted or unsubstituted triphenylenylene group, a substituted or unsubstituted pyrenylene group, a substituted or unsubstituted chrysenylene group, a substituted or unsubstituted naphthacenylene group, a substituted or unsubstituted picenylene group, a substituted or unsubstituted perylenylene group, a substituted or unsubstituted pentaphenylene group, a substituted or unsubstituted hexacenylene group, a substituted or unsubstituted pyrrolylene group, a substituted or unsubstituted pyrazolylene group, a substituted or unsubstituted imidazolylene group, a substituted or unsubstituted imidazolinylene group, a substituted or unsubstituted imidazopyridinylene group, a substituted or unsubstituted imidazopyrimidinylene group, a substituted or unsubstituted pyridinylene group, a substituted or unsubstituted pyrazinylene group, a substituted or unsubstituted pyrimidinylene group, a substituted or unsubstituted indolylene group, a substituted or unsubstituted purinylene group, a substituted or unsubstituted quinolinylene group, a substituted or unsubstituted phthalazinylene group, a substituted or unsubstituted indolizinylene group, a substituted or unsubstituted naphthyridinylene group, a substituted or unsubstituted quinazolinylene group, a substituted or unsubstituted cinnolinylene group, a substituted or unsubstituted indazolylene group, a substituted or unsubstituted carbazolylene group, a substituted or unsubstituted phenazinylene group, a substituted or unsubstituted phenanthridinylene group, a substituted or unsubstituted pyranylene group, a substituted or unsubstituted chromenylene group, a substituted or unsubstituted furanylene group, a substituted or unsubstituted benzofuranylene group, a substituted or unsubstituted thiophenylene group, a substituted or unsubstituted benzothiophenylene group, a substituted or unsubstituted isothiazolylene group, a substituted or unsubstituted benzoimidazolylene group, a substituted or unsubstituted isoxazolylene group, a substituted or unsubstituted dibenzothiophenylene group, a substituted or unsubstituted dibenzopuranylene group, a substituted or unsubstituted triazinylene group, and a substituted or unsubstituted oxadiazolylene group, and p, q, and r are each independently one of integers of 0 to 1.

In Formula 4, when p, q, and r are each independently 0, -(L₁₁)ₚ—, -(L₁₂)_{q}—, and -(L₁₃)ᵣ- each independently represents a single bond.

For example, as the material for forming an electron transport layer, the compound represented by Formula 4 above or a mixture of the compound represented by Formula 4 above and a commonly known material for forming an electron transport layer may be used.

The compound represented by Formula 4 above may be Compound 201 below, but is not limited thereto:

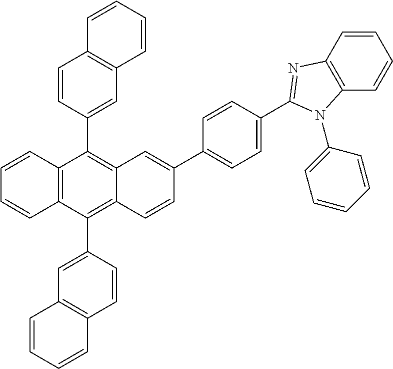 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

An example of the commonly known material for an electron transport layer may be a material such as a quinoline derivative, particularly tris(8-quinolinolato)aluminum (Alq3), TAZ, Balq, beryllium bis(benzoquinolin-10-olate (Bebq₂), or ADN, but is not limited thereto.

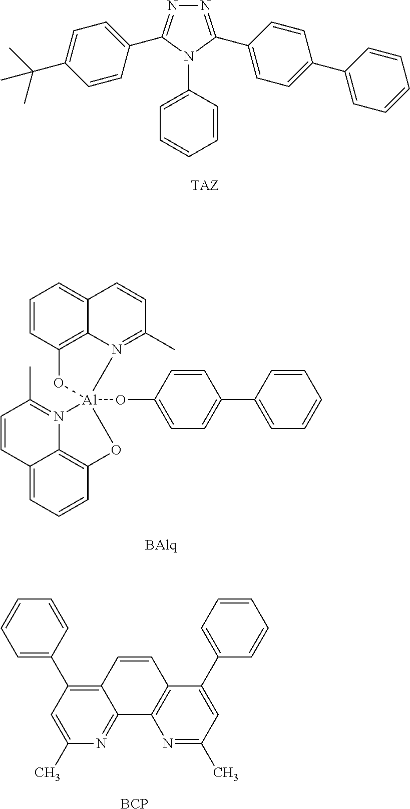

In some embodiments, the thickness of the electron transport layer 373 may be in a range from about 50 Å to about 1000 Å, for example, from about 100 Å to about 500 Å. If the thickness of the electron transport layer 373 is within the range above, an excellent electron transporting ability may be obtained without a substantial increase of driving voltage.

The electron transport layer 373 may further include a metal-contained compound as well as the compound represented by Formula 4 above.

The metal-contained compound may be a Li-complex. The Li-complex may be, for example, a lithium quinolate (LiQ), Compound 101 below, or the like:

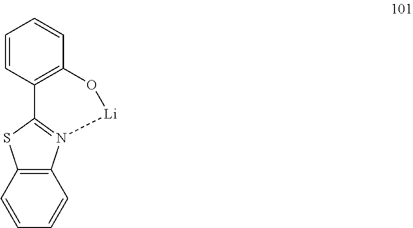

The electron transport layer 373 may further include at least one selected from 1,4,5,8,9,12-hexaazatriphenylene hexacarbonitrile, tetracyanoquinodimethane, anthraquinone, perylenebisimide, and tetracyanoanthraquinodimethane as well as the compound represented by Formula 4.

The electron transport layer 373 may further include at least one selected from at least one metal selected from Li, Cs, Na, K, Ca, Mg, Ba, and Ra; metal carbonate; metal acetate; metal benzoate; metal acetoacetate; metal acetylacetonate; and metal stearate as well as the compound represented by Formula 4.

If the electron transport layer 373 includes the materials described above as well as the compound represented by Formula 4, electron injection and transportation ability may be improved.

The electron injection layer 375 which serves to fasten injection of electrons from the cathode may be disposed on the electron transport layer 373, and a material for the electron injection layer 375 is not particularly limited.

As a material for forming an electron injection layer may be a commonly known material such as LiF, NaCl, CsF, Li₂O, BaO, or the like. Although conditions for deposition and coating may vary according to the compound that is used for forming the electron injection layer 375, generally the conditions for deposition and coating may be similar to those for the formation of the hole injection layer 383.

A thickness of the electron injection layer 375 may be in a range from about 1 Å to about 100 Å, for example, from about 3 Å to about 90 Å. If the thickness of the electron injection layer 375 is within the range above, an excellent electron injecting ability may be obtained without a substantial increase of driving voltage.

The second electrode 390 is disposed on the organic layer 350. The second electrode 390 may be the cathode which is an electron injecting electrode, and a material used for forming a second electrode may be a metal, an alloy, a conductive compound, or a mixture thereof which has a low work-function. For detailed example, a Li, Mg, Al, Al—Li, Ca, Mg—In, or Mg—Ag are formed as a thin film to obtain a transparent electrode. Meanwhile, various modifications such as forming a transmissive electrode using ITO or IZO in order to obtain a top-emission device are possible.

The OLED 300 having such construction may have an excellent luminous efficiency at a high luminance region and a low luminous efficiency at a low luminance region since a flow of electrons injected from the electron transport layer 373 to the emission layer 360 is controlled due to an effect of the electron control layer 371.

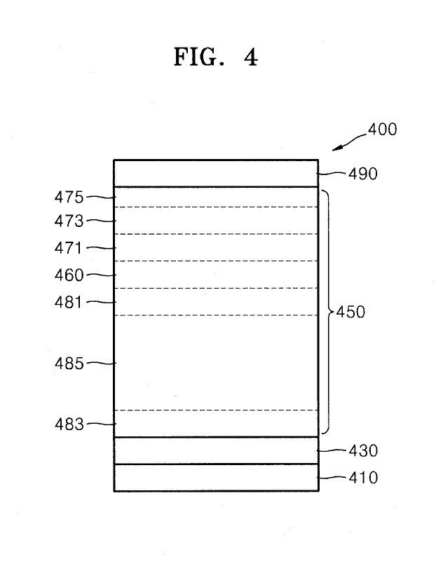

FIG. 4 is a schematic cross-sectional view of an OLED 400 having a structure of a substrate 410/a first electrode 430/a hole injection layer 483/a hole transport layer 485/an electron blocking layer 481/an emission layer 460/an electron control layer 471/an electron transport layer 473/an electron injection layer 475/a second electrode 490 according to an embodiment.

The detailed description of the substrate 410, the first electrode 430, the hole injection layer 483, the hole transport layer 485, the emission layer 460, the electron control layer 471, the electron transport layer 473, the electron injection layer 475, and the second electrode 490 may be referred to the description of FIG. 3.

The electron blocking layer 481 may be disposed between at least one of the hole injection layer 483, the hole transport layer 485, and a functional layer (not shown) having hole injection and transport ability, and the emission layer 460. The electron blocking layer 481 may serve to prevent electrons that are not combined with holes in the emission layer 460 from moving in a direction to the first electrode 430. The electron blocking layer 481 may be formed using the electron blocking material, and the electron blocking material may be, for example, at least one of a triphenylamine derivative, a carbazole derivative, or a spirobifluorene derivative.

In some embodiments, the thickness of the electron blocking layer 481 may be in a range from about 10 Å to about 1000 Å, for example, from about 50 Å to about 800 Å. If the thickness of the electron blocking layer 481 is within the range above, an excellent electron blocking ability may be obtained without a substantial increase of driving voltage.

The OLED 400 having such construction may have an excellent luminous efficiency at a high luminance region and a low luminous efficiency at a low luminance region since a flow of electrons injected from the electron transport layer 473 to the emission layer 460 is controlled due to an effect of the electron control layer 471 and the electron blocking layer 481.

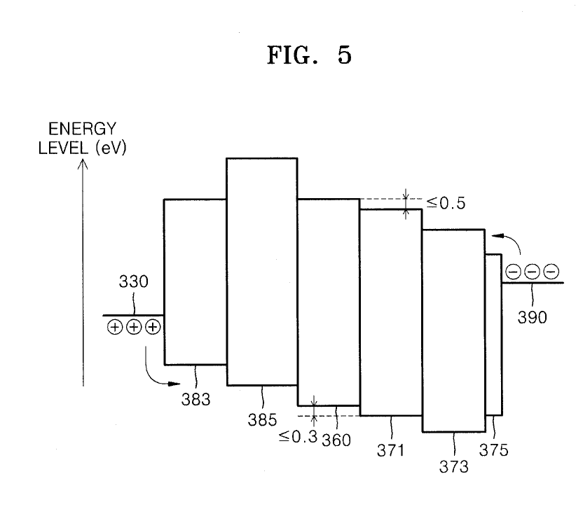

FIG. 5 schematically illustrates HOMO energy level and LUMO energy level of each layer in the OLED 300 shown in FIG. 3.

HOMO energy level of the electron control layer 371 including the electron control material is lower than HOMO energy level of the emission layer 360 including the host material, and a difference therebetween is about 0.3 eV or less. Also, LUMO energy level of the emission layer 360 is lower than the HOMO energy level of the emission layer 360, and a difference therebetween is about 0.5 eV or less.

Due to such relationships, luminance of a device is improved by the electron control layer 371 blocking holes that are to transpass the electron control layer 371 from the emission layer 360 at a high luminance region, and luminance of a device is lowered by the electron control layer 371 facilitating holes from the emission layer 360 to move to the electron transport layer 371 through transpassing the electron control layer 371 at a low luminance region.

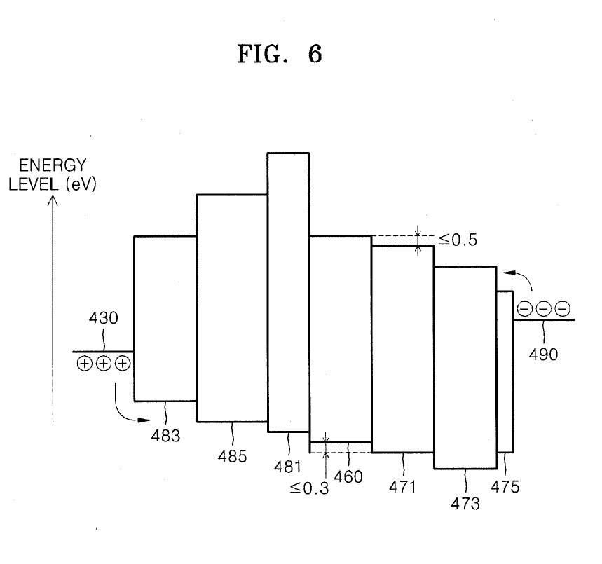

FIG. 6 schematically illustrates HOMO energy level and LUMO energy level of each layer in the OLED 400 shown in FIG. 4.

HOMO energy level of the electron control layer 471 including the electron control material is lower than HOMO energy level of the emission layer 460 including the host material, and a difference therebetween is about 0.3 eV or less. Also, LUMO energy level of the emission layer 460 is lower than the HOMO energy level of the emission layer 460, and a difference therebetween is about 0.5 eV or less.

In some embodiments, the electron blocking layer 481 including the electron blocking material is disposed between the emission layer 460 and the first electrode 430 and, in this case, is close to the emission layer 460. LUMO energy level of the electron blocking layer 481 is higher than the LUMO energy of the emission layer 460.

Due to such relationships, luminance of a device is improved by the electron control layer 471 blocking holes that are to transpass the electron control layer 471 from the emission layer 460 and the electron blocking layer 481 blocking electrons that are not combined with holes in the emission layer 460 from moving in a direction to the first electrode 430 at a high luminance region and luminance of a device is lowered by the electron transport layer 471 facilitating electrons to move from the emission layer 460 to the electron control layer 471 through transpassing the electron control layer 471 at a low luminance region.

An organic light-emitting display apparatus according to another embodiment includes a transistor including source, drain, gate, and an active layer, and an OLED described above, and a first electrode of the OLED is electrically connected to the source or the drain.

The active layer of the transistor may be an amorphous silicon layer, a crystalline silicon layer, an organic semiconductor layer, or an oxide semiconductor layer.

Such OLED may have improved luminous efficiency characteristics according to luminance as emitting red and green light is suppressed in a black state.

As used herein, an example of “an unsubstituted C₁-C₃₀ alkyl group” (or “a C₁-C₃₀ alkyl group”) may be a linear or branched alkyl group with 1 to 30 carbon atoms such as methyl, ethyl, propyl, isobutyl, sec-butyl, pentyl, iso-amyl, or hexyl, and a substituted C₁-C₃₀ alkyl group refers to the unsubstituted C₁-C₃₀ alkyl group in which at least one hydrogen is substituted with a deuterium, a halogen, a hydroxyl group, a nitro group, a cyano group, an amino group, an amidino group, a hydrazine, a hydrazone, a carboxylic group or a salt thereof, a sulfonic acid group or a salt thereof, a phosphoric acid group or a salt thereof, a C₁-C₃₀ alkyl group, a C₂-C₃₀ alkenyl group, a C₂-C₃₀ alkynyl group, a C₆-C₃₀ aryl group, a C₂-C₃₀ heteroaryl group, —N(Q₁₀₁)(Q₁₀₂), or Si(Q₁₀₃)(Q₁₀₄)(Q₁₀₅)(Q₁₀₆)- (here, Q₁₀₁ to Q₁₀₆ are each independently selected from the group consisting of a hydrogen, a C₁-C₃₀ alkyl group, a C₂-C₃₀ alkenyl group, a C₂-C₃₀ alkynyl group, a C₆-C₃₀ aryl group, and a C₂-C₃₀ heteroaryl group).

As used herein, an unsubstituted C₁-C₃₀ alkoxy group (or a C₁-C₃₀ alkoxy group) has a formula represented by —OA, where A is the unsubstituted C₁-C₃₀ alkyl group as defined above. An example of the unsubstituted C₁-C₃₀ alkoxy group may be methoxy, ethoxy, or isopropyloxy. The substituted C₁-C₃₀ alkoxy group refers to a C₁-C₃₀ alkoxy group in which at least one hydrogen is substituted with any one of the substituents presented in the case of the substituted C₁-C₃₀ alkyl group, which is described above.

As used herein, an unsubstituted C₂-C₃₀ alkenyl group (or a C₂-C₃₀ alkenyl group) refers to the unsubstituted C₂-C₃₀ alkenyl group having one or more carbon-carbon double bonds at the center or at a terminal of the unsubstituted C₂-C₃₀ alkyl group. An example of the unsubstituted C₂-C₅₀ alkenyl group may be an ethenyl group, a propenyl group, or a butenyl group. The substituted C₂-C₃₀ alkenyl group refers to a C₂-C₃₀ alkenyl group in which at least one hydrogen is substituted with any one of the substituents presented in the case of the substituted C₁-C₃₀ alkyl group, which is described above.

As used herein, an unsubstituted C₂-C₃₀ alkynyl group (or a C₂-C₃₀ alkynyl group) refers to the unsubstituted C₂-C₃₀ alkynyl group having at least one carbon-carbon triple bond at the center or at a terminal of the substituted and unsubstituted C₂-C₃₀ alkyl group. The substituted C₂-C₃₀ alkynyl group refers to a C₂-C₃₀ alkynyl group in which at least one hydrogen is substituted with any one of the substituents presented in the case of the substituted C₁-C₃₀ alkyl group, which is described above.

As used herein, the unsubstituted C₆-C₃₀ aryl group refers to a monovalent group having a carbocyclic aromatic system in which the number of carbon atoms is 5 to 30, and the unsubstituted C₆-C₃₀ arylene group refers to a divalent group having a carbocyclic aromatic system in which the number of carbon atoms is 5 to 30. If the unsubstituted C₆-C₃₀ aryl group and the unsubstituted C₆-C₃₀ arylene group include two or more rings, the rings may be fused to one another. The substituted C₆-C₃₀ aryl group refers to a C₆-C₃₀ aryl group in which at least one hydrogen is substituted with any one of the substituents presented in the case of the substituted C₁-C₃₀ alkyl group, which is described above, and the substituted C₆-C₃₀ arylene group refers to a C₆-C₃₀ arylene group in which at least one hydrogen is substituted with any one of the substituents presented in the case of the substituted C₁-C₃₀ alkyl group, which is described above.

As used herein, the unsubstituted C₂-C₃₀ heteroaryl group refers to a monovalent group having a carbocyclic aromatic system with at least one ring having one or more heteroatoms selected from the group consisting of nitrogen (N), oxygen (O), phosphorous (P), and sulfur (S), and the rest ring atoms are C. The unsubstituted C₂-C₃₀ heteroarylene group refers to a divalent group having a carbocyclic aromatic system with at least one ring having one or more heteroatoms selected from the group consisting of N, O, P, and S, and the rest ring atoms are C. Here, if the unsubstituted C₂-C₃₀ heteroaryl group and the unsubstituted C₂-C₃₀ heteroarylene group include two or more rings, the rings may be fused to one another. The substituted C₂-C₃₀ heteroaryl group refers to a C₂-C₃₀ heteroaryl group in which at least one hydrogen is substituted with any one of the substituents presented in the case of the substituted C₁-C₃₀ alkyl group, which is described above, and the substituted C₂-C₃₀ heteroarylene group refers to a C₂-C₃₀ heteroarylene group in which at least one hydrogen is substituted with any one of the substituents presented in the case of the substituted C₁-C₃₀ alkyl group, which is described above.

As used herein, an unsubstituted C₆-C₃₀ aryloxy group refers to —OA₂ (here, A₂ is a substituted or unsubstituted C₆-C₃₀ aryl group), and the substituted C₆-C₃₀ aryloxy group refers to a C₆-C₃₀ aryloxy group in which at least one hydrogen is substituted with any one of the substituents presented in the case of the substituted C₁-C₃₀ alkyl group, which is described above.

As used herein, an unsubstituted C₆-C₃₀ arylthio group refers to —SA₃ (here, A₃ is a substituted or unsubstituted C₃-C₃₀ aryl group), and the substituted C₆-C₃₀ arylthio group refers to a C₆-C₃₀ arylthio group in which at least one hydrogen is substituted with any one of the substituents presented in the case of the substituted C₁-C₃₀ alkyl group, which is described above.

Hereinafter, an OLED according to an embodiment will be described in detail with reference to Examples. However, the present embodiments are not limited to Examples below.

### Example 1

As an anode, an ITO(7 nm)/Ag(100 nm)/ITO(7 nm) substrate of Samsung Mobile Display (SMD) using glass manufactured by Corning Co., Ltd was cut to a size of 50 mm×50 mm×0.7 mm, sonicated with pure water and isopropyl alcohol each for 30 minutes, exposed to a ultraviolet ray and ozone for 10 minutes, and then the resultant was installed in a vacuum deposition device.

Compound 301 was vacuum deposited on the glass substrate to form a hole injection layer having a thickness of 750 Å, and then Compound 311 was vacuum deposited on the hole injection layer to form a hole transport layer having a thickness of 1300 Å.

Compound 507 as a host and Compound 401 as a phosphorescent dopant were co-deposited on the hole transport layer at a weight ratio of 98:2 to form a red emission layer having a thickness of 400 Å.

Subsequently, Compound 1 was vacuum deposited on the emission layer to form an electron control layer having a thickness of 50 Å.

Compound 201 (same as Compound 1) and LiQ were vacuum co-deposited on the electron control layer at a weight ratio of 1:1 to form an electron transport layer having a thickness of 100 Å.

LiQ was vacuum deposited on the electron transport layer to form an electron injection layer having a thickness of 5 Å, and then Mg and Ag were vacuum deposited on the electron injection layer at a weight ratio of 10:1 to form a cathode having a thickness of 130 Å, thereby an OLED was manufactured.

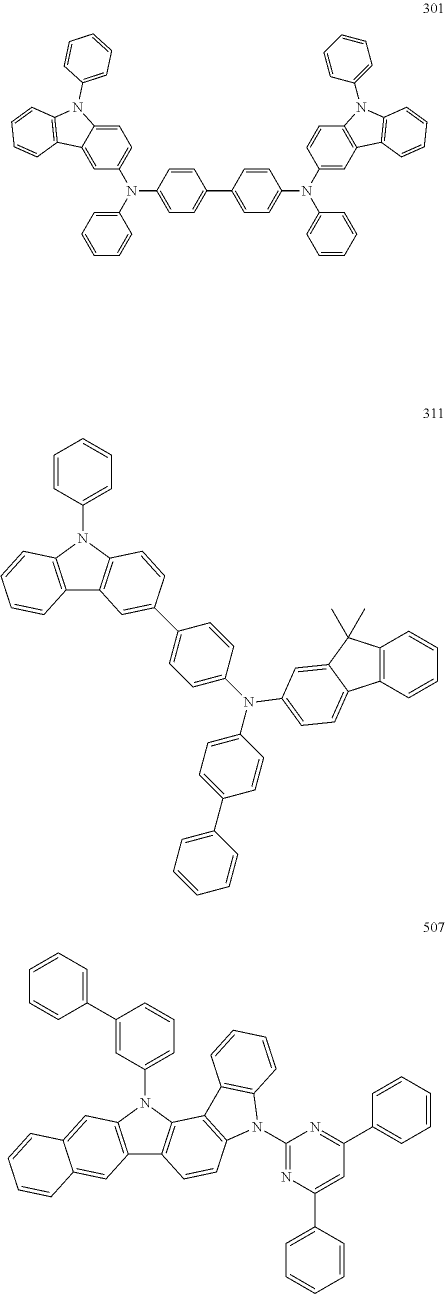 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2cccc(-n3c4cc5ccccc5cc4c4ccc5c(c6ccccc6n5-c5nc(-c6ccccc6)cc(-c6ccccc6)n5)c43)c2)cc1]

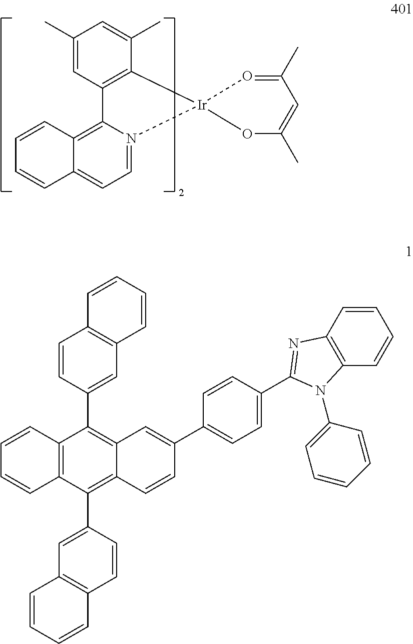

### Example 2

An OLED was manufactured in the same manner as in Example 1, except that an electron control layer was formed to have a thickness of 100 Å instead of 50 Å.

### Example 3

An OLED was manufactured in the same manner as in Example 1, except that an electron control layer was formed to have a thickness of 200 Å instead of 50 Å.

### Example 4

An OLED was manufactured in the same manner as in Example 1, except that an electron control layer was formed to have a thickness of 450 Å instead of 50 Å.

### Example 5

An OLED was manufactured in the same manner as in Example 1, except that Compound 701 below was vacuum deposited between a hole transport layer and an emission layer to form an electron blocking layer having a thickness of 300 Å, and an electron control layer was formed to have a thickness of 100 Å instead of 50 Å.

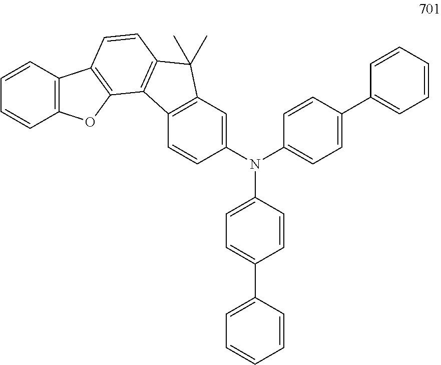 [SMILES: CC1(C)c2cc(N(c3ccc(-c4ccccc4)cc3)c3ccc(-c4ccccc4)cc3)ccc2-c2c1ccc1c2oc2ccccc21]

### Example 6

An OLED was manufactured in the same manner as in Example 1, except that Compound 701 was vacuum deposited between a hole transport layer and an emission layer to form an electron blocking layer having a thickness of 300 Å, and an electron control layer was formed to have a thickness of 200 Å instead of 50 Å.

### Comparative Example 1

An OLED was manufactured in the same manner as in Example 1, except that an electron control layer was not formed.

### Comparative Example 2

An OLED was manufactured in the same manner as in Example 5, except that an electron control layer was not formed.

### Comparative Example 3

An OLED was manufactured in the same manner as in Example 3, except that Compound 601 below was used to form a layer having a thickness of 200 Å instead of vacuum depositing Compound 1 to form an electron control layer having a thickness of 200 Å.

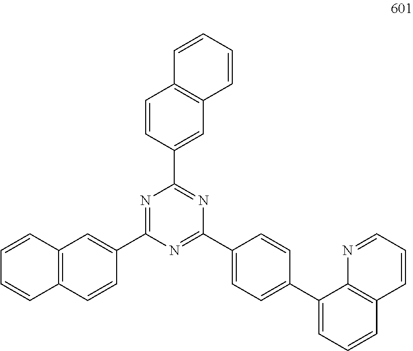 [SMILES: c1ccc2cc(-c3nc(-c4ccc(-c5cccc6cccnc56)cc4)nc(-c4ccc5ccccc5c4)n3)ccc2c1]

### Comparative Example 4

An OLED was manufactured in the same manner as in Example 4, except that Compound 601 was used to form a layer having a thickness of 450 Å instead of vacuum depositing Compound 1 to form an electron control layer having a thickness of 450 Å.

### Example 7

As an anode, an ITO(7 nm)/Ag(100 nm)/ITO(7 nm) substrate of Samsung Mobile Display (SMD) using glass manufactured by Corning Co., Ltd was cut to a size of 50 mm×50 mm×0.7 mm, sonicated with pure water and isopropyl alcohol each for 30 minutes, exposed to a ultraviolet ray and ozone for 10 minutes, and then the resultant was installed in a vacuum deposition device.

Compound 301 was vacuum deposited on the glass substrate to form a hole injection layer having a thickness of 750 Å, and then Compound 311 was vacuum deposited on the hole injection layer to form a hole transport layer having a thickness of 1300 Å.

Compound 701 was vacuum deposited on the hole transport layer to form an electron blocking layer having a thickness of 300 Å.

Compound 508 as a host and Compound 402 as a phosphorescent dopant were co-deposited on the electron blocking layer at a weight ratio of 95:5 to form a green emission layer having a thickness of 400 Å.

Subsequently, Compound 1 was vacuum deposited on the emission layer to form an electron control layer having a thickness of 50 Å.

Compound 201 (same as Compound 1) and LiQ were vacuum co-deposited on the electron control layer at a weight ratio of 1:1 to form an electron transport layer having a thickness of 100 Å.

LiQ was vacuum deposited on the electron transport layer to form an electron injection layer having a thickness of 5 Å, and then Mg and Ag were vacuum deposited on the electron injection layer at a weight ratio of 10:1 to form a cathode having a thickness of 130 Å, thereby an OLED was manufactured.

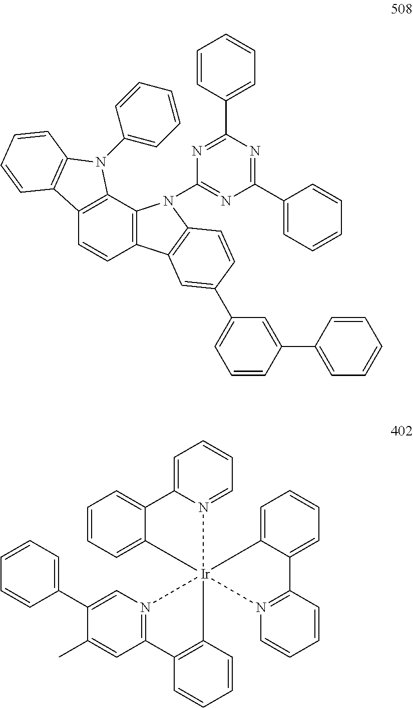

### Example 8

An OLED was manufactured in the same manner as in Example 7, except that an electron control layer was formed to have a thickness of 100 Å instead of 50 Å.

### Example 9

An OLED was manufactured in the same manner as in Example 7, except that an electron control layer was formed to have a thickness of 200 Å instead of 50 Å.

### Example 10

An OLED was manufactured in the same manner as in Example 7, except that an electron blocking layer was not formed and an electron control layer was formed to have a thickness of 200 Å instead of 50 Å.

### Comparative Example 5

An OLED was manufactured in the same manner as in Example 10, except that an electron blocking layer was not formed.

### Comparative Example 6

An OLED was manufactured in the same manner as in Example 7, except that an electron blocking layer was not formed.

### Comparative Example 7

An OLED was manufactured in the same manner as in Example 9, except that Compound 601 was used to form a layer having a thickness of 200 Å instead of vacuum depositing Compound 1 to form an electron control layer having a thickness of 200 Å.

### Example 11

As an anode, an ITO(7 nm)/Ag(100 nm)/ITO(7 nm) substrate of Samsung Mobile Display (SMD) using glass manufactured by Corning Co., Ltd was cut to a size of 50 mm×50 mm×0.7 mm, sonicated with pure water and isopropyl alcohol each for 30 minutes, exposed to a ultraviolet ray and ozone for 10 minutes, and then the resultant was installed in a vacuum deposition device.

Compound 301 was vacuum deposited on the glass substrate to form a hole injection layer having a thickness of 750 Å, and then Compound 311 was vacuum deposited on the hole injection layer to form a hole transport layer having a thickness of 1300 Å.

A mixture of Compound 504 and Compound 509 at a weight ratio of 2:8 as a host and Compound 402 as a phosphorescent dopant were co-deposited on the hole transport layer at a weight ratio of 85:15 to form a green emission layer having a thickness of 400 Å.

Subsequently, Compound 1 was vacuum deposited on the emission layer to form an electron control layer having a thickness of 50 Å.

Compound 201 (same as Compound 1) and LiQ were vacuum co-deposited on the electron control layer at a weight ratio of 1:1 to form an electron transport layer having a thickness of 100 Å.

LiQ was vacuum deposited on the electron transport layer to form an electron injection layer having a thickness of 5 Å, and then Mg and Ag were vacuum deposited on the electron injection layer at a weight ratio of 10:1 to form a cathode having a thickness of 130 Å, thereby an OLED was manufactured.

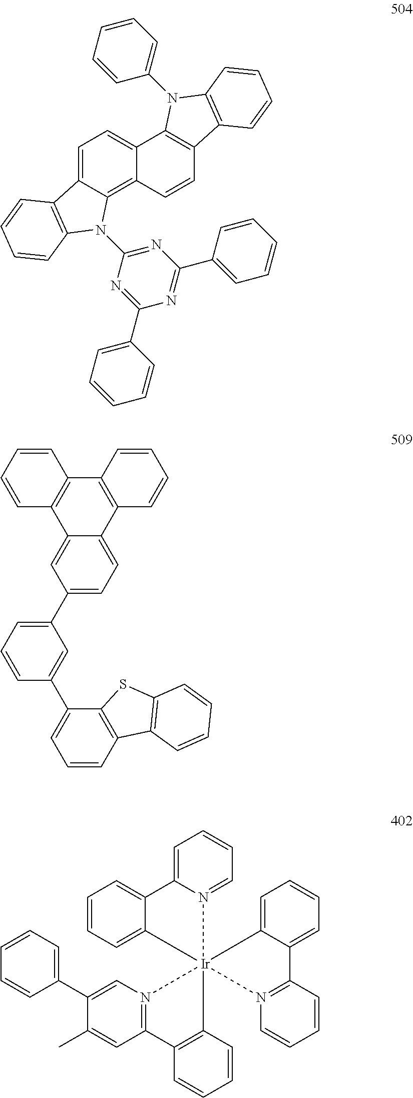

### Example 12

An OLED was manufactured in the same manner as in Example 11, except that an electron control layer was formed to have a thickness of 100 Å instead of 50 Å.

### Example 13

An OLED was manufactured in the same manner as in Example 11, except that an electron control layer was formed to have a thickness of 200 Å instead of 50 Å.

### Example 14

An OLED was manufactured in the same manner as in Example 11, except that Compound 701 was vacuum deposited between a hole transport layer and an emission layer to form an electron blocking layer having a thickness of 300 Å, and an electron control layer was formed to have a thickness of 100 Å instead of 50 Å.

### Comparative Example 8

An OLED was manufactured in the same manner as in Example 11, except that an electron control layer was not formed.

### Comparative Example 9

An OLED was manufactured in the same manner as in Example 14, except that an electron control layer was not formed.

### Comparative Example 10

An OLED was manufactured in the same manner as in Example 13, except that Compound 601 was used to form a layer having a thickness of 200 Å instead of vacuum depositing Compound 1 to form an electron control layer having a thickness of 200 Å.

Experimental conditions above were summarized and shown in Table 1 below.

TABLE 1

| | | | | | | | | Electron blocking | |
|---|---|---|---|---|---|---|---|---|---|
| | Electron control layer | | | | | | | layer | |
| | Electron | | | Thick- | Emission layer | | | Electron | |
| | control | HOMO | LUMO | ness | | HOMO | LUMO | blocking | LUMO |
| Classification | material | (eV) | (eV) | (Å) | Host Material | (eV) | (eV) | material | (eV) |
| Example 1 | Compound | −5.6 | −2.8 | 50 | Compound 507 | −5.6 | −2.8 | — | — |
| | 1 | | | | | | | | |
| Example 2 | Compound | −5.6 | −2.8 | 100 | Compound 507 | −5.6 | −2.8 | — | — |
| | 1 | | | | | | | | |
| Example 3 | Compound | −5.6 | −2.8 | 200 | Compound 507 | −5.6 | −2.8 | — | — |
| | 1 | | | | | | | | |
| Example 4 | Compound | −5.6 | −2.8 | 450 | Compound 507 | −5.6 | −2.8 | — | — |
| | 1 | | | | | | | | |
| Example 5 | Compound | −5.6 | −2.8 | 100 | Compound 507 | −5.6 | −2.8 | Compound | −2.1 |
| | 1 | | | | | | | 701 | |
| Example 6 | Compound | −5.6 | −2.8 | 200 | Compound 507 | −5.6 | −2.8 | Compound | −2.1 |
| | 1 | | | | | | | 701 | |
| Comparative | — | — | — | — | Compound 507 | −5.6 | −2.8 | — | — |
| Example 1 | | | | | | | | | |
| Comparative | — | — | — | — | Compound 507 | −5.6 | −2.8 | Compound | −2.1 |
| Example 2 | | | | | | | | 701 | |
| Comparative | Compound | −6.3 | −3.1 | 200 | Compound 507 | −5.6 | −2.8 | — | — |
| Example 3 | 601 | | | | | | | | |
| Comparative | Compound | −6.3 | −3.1 | 450 | Compound 507 | −5.6 | −2.8 | — | — |
| Example 4 | 601 | | | | | | | | |
| Example 7 | Compound | −5.6 | −2.8 | 50 | Compound 508 | −5.7 | −2.6 | Compound | −2.1 |
| | 1 | | | | | | | 701 | |
| Example 8 | Compound | −5.6 | −2.8 | 100 | Compound 508 | −5.7 | −2.6 | Compound | −2.1 |
| | 1 | | | | | | | 701 | |
| Example 9 | Compound | −5.6 | −2.8 | 200 | Compound 508 | −5.7 | −2.6 | Compound | −2.1 |
| | 1 | | | | | | | 701 | |
| Example 10 | Compound | −5.6 | −2.8 | 200 | Compound 508 | −5.7 | −2.6 | — | — |
| | 1 | | | | | | | | |
| Comparative | — | — | — | — | Compound 508 | −5.7 | −2.6 | — | — |
| Example 5 | | | | | | | | | |
| Comparative | — | — | — | — | Compound 508 | −5.7 | −2.6 | Compound | −2.1 |
| Example 6 | | | | | | | | 701 | |
| Comparative | Compound | −6.3 | −3.1 | 200 | Compound 508 | −5.7 | −2.6 | Compound | −2.1 |
| Example 7 | 601 | | | | | | | 701 | |
| Example 11 | Compound | −5.6 | −2.8 | 50 | Compounds | −5.9 | −2.9 | — | — |
| | 1 | | | | 504 and 509 | −5.8 | −2.1 | | |
| Example 12 | Compound | −5.6 | −2.8 | 100 | Compounds | −5.9 | −2.9 | — | — |
| | 1 | | | | 504 and 509 | −5.8 | −2.1 | | |
| Example 13 | Compound | −5.6 | −2.8 | 200 | Compounds | −5.9 | −2.9 | — | — |
| | 1 | | | | 504 and 509 | −5.8 | −2.1 | | |
| Example 14 | Compound | −5.6 | −2.8 | 100 | Compounds | −5.9 | −2.9 | Compound | −2.1 |
| | 1 | | | | 504 and 509 | −5.8 | −2.1 | 701 | |
| Comparative | — | — | — | — | Compounds | −5.9 | −2.9 | — | — |
| Example 8 | | | | | 504 and 509 | −5.8 | −2.1 | | |
| Comparative | — | — | — | — | Compounds | −5.9 | −2.9 | Compound | −2.1 |
| Example 9 | | | | | 504 and 509 | −5.8 | −2.1 | 701 | |
| Comparative | Compound | −6.3 | −3.1 | 200 | Compounds | −5.9 | −2.9 | — | — |
| Example 10 | 601 | | | | 504 and 509 | −5.8 | −2.1 | | |

### Evaluation Example

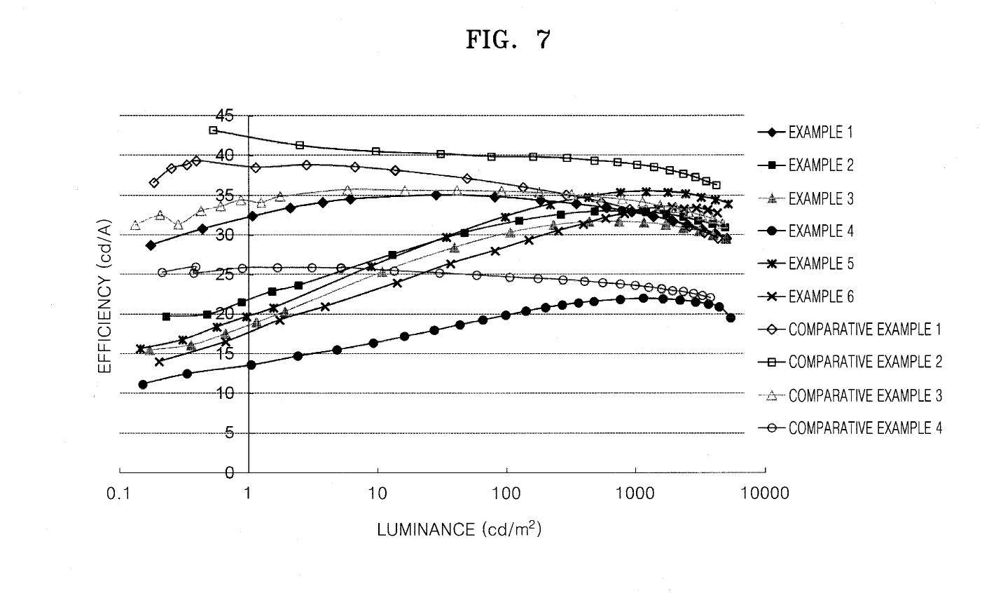

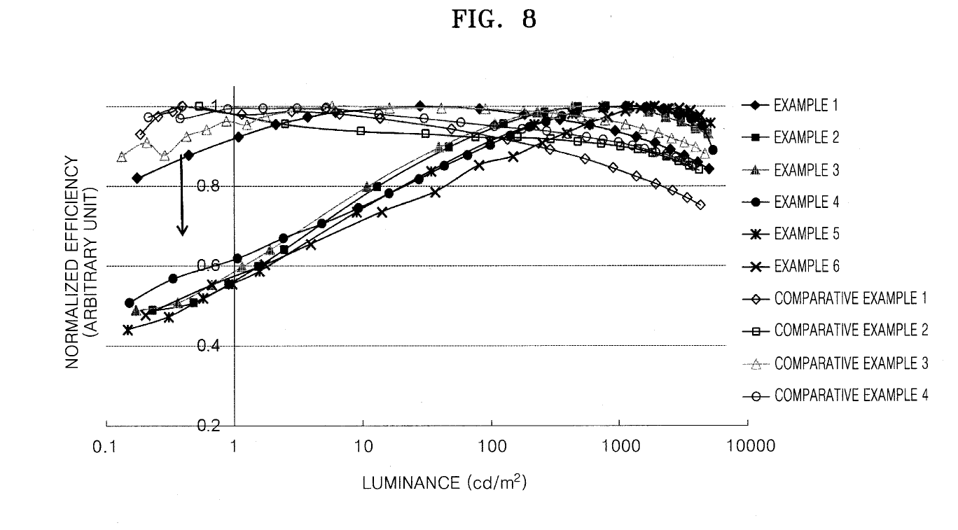

Red light-emitting efficiencies of the OLEDs manufactured according to Examples 1 to 6 and Comparative Examples 1 to 4 were measured while changing a luminance in a range from 0.1 cd/m² to 10,000 cd/m². The results were shown in FIG. 7, and the normalized results were shown in FIG. 8.

Referring to FIG. 7, the OLEDs manufactured in Examples 1 to 6 generally showed lower light-emitting efficiencies than the OLEDs manufactured in Comparative Example 1 to 4 at a low luminance.

Referring to FIG. 8 which is a normalized graph of a graph in FIG. 7, the OLEDs manufactured in Examples 1 to 6 showed similar level of light-emitting efficiencies with the OLEDs manufactured in Comparative Examples 1 to 4 at a high luminance region of about 100 cd/m² or higher. However, the OLEDs manufactured in Examples 1 to 6 showed very low level of light-emitting efficiencies compared to the OLEDs manufactured in Comparative Examples 1 to 4 at a low luminance region of around about 1 cd/m². An arrow on the graph is to indicate reduction of light-emitting efficiencies.

S-ratios were calculated, and the results were shown in Table 2 in order to confirm a degree of improvement of luminous efficiency characteristics of the OLEDs manufactured in Examples 1 to 6 and Comparative Examples 1 to 4 according to luminance.

TABLE 2

| | | | | | | | Comparative | Comparative | Comparative | Comparative |
|---|---|---|---|---|---|---|---|---|---|---|
| | Example | Example | Example | Example | Example | Example | Example | Example | Example | Example |
| | 1 | 2 | 3 | 4 | 5 | 6 | 1 | 2 | 3 | 4 |
| Efficiency @ | 32.2 | 21.8 | 18.6 | 13.6 | 19.8 | 17.5 | 38.7 | 42.8 | 34.4 | 25.9 |
| 1 cd/m² | | | | | | | | | | |
| Efficiency @ | 32.8 | 33.0 | 31.7 | 22.0 | 35.5 | 33.1 | 33.1 | 38.9 | 34.4 | 23.7 |
| 1,000 cd/m² | | | | | | | | | | |
| S-ratio | 1.02 | 1.51 | 1.70 | 1.62 | 1.79 | 1.90 | 0.85 | 0.91 | 1.00 | 0.91 |

An S-ratio is defined as a ratio of a current efficiency value at 1,000 cd/m² divided by a current efficiency value at 1 cd/m². As the S-ratio is increased, a shape of a luminance vs. efficiency graph is closer to S which indicates that the OLEDs have a great tendency to have a high luminous efficiency at a high luminance region and a low luminous efficiency at a low luminance region.

Referring to Table 2, unlike the S-ratios of the OLEDs manufactured in Examples 1 to 6 were all greater than 1 and reached almost 2 in the case of Example 6, the S-ratios of the OLEDs manufactured in Comparative Examples 1 to 4 were 1 or lower. That is, a shape of the luminance vs. efficiency graph of the OLEDs manufactured in Examples 1 to 6 is closer to S than that of the OLEDs manufactured in Comparative Examples 1 to 4.

In the regard, it may be confirmed that the OLEDs manufactured in Examples 1 to 6 have improved luminous efficiency characteristics according to luminance as the OLEDs show high red light-emitting efficiencies at a high luminance region and very low red light-emitting efficiencies at a low luminance region.

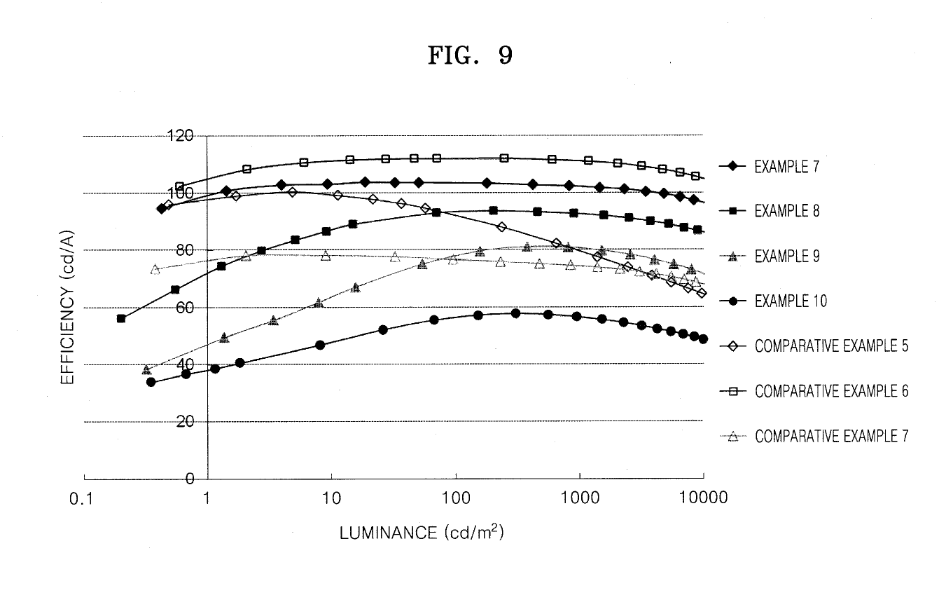

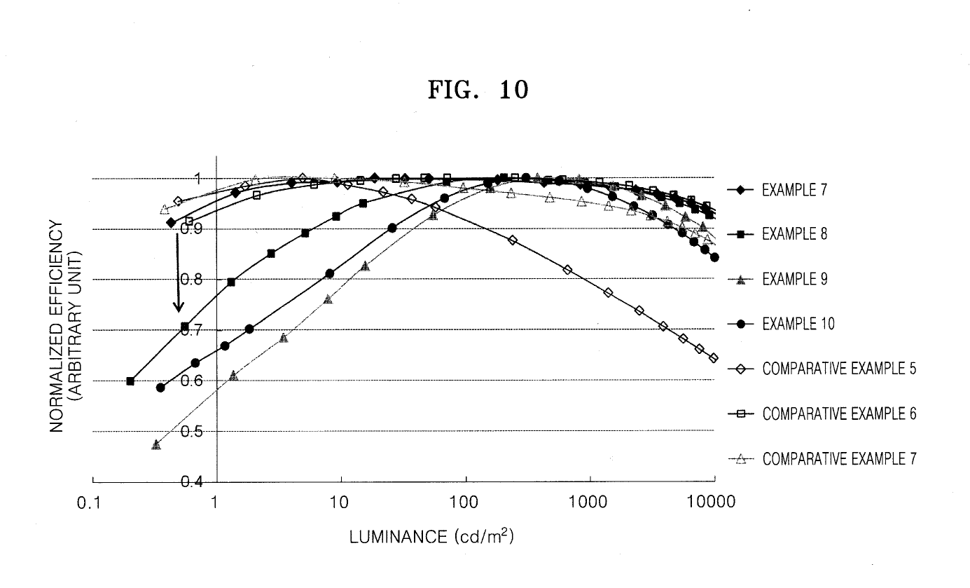

Green light-emitting efficiencies of the OLEDs manufactured according to Examples 7 to 10 and Comparative Examples 5 to 7 were measured while changing a luminance in a range from 0.1 cd/m² to 10,000 cd/m². The results were shown in FIG. 9, and the normalized results were shown in FIG. 10.

Referring to FIG. 9, the OLEDs manufactured in Examples 8 to 10 generally showed lower light-emitting efficiencies than the OLEDs manufactured in Comparative Example 5 to 7 at a low luminance. The OLED manufactured in Example 7 showed a similar level of luminous efficiency with the OLEDs manufactured in Comparative Examples 5 to 7.

Referring to FIG. 10 which is a normalized graph of a graph in FIG. 9, the OLEDs manufactured in Examples 8 to 10 showed similar levels of light-emitting efficiencies with the OLEDs manufactured in Comparative Examples 5 to 7 at a high luminance region of about 100 cd/m² or higher. However, the OLEDs manufactured in Examples 8 to 10 showed low level of light-emitting efficiencies compared to the OLEDs manufactured in Comparative Examples 5 to 7 at a low luminance region of around about 1 cd/m². An arrow on the graph is to indicate reduction of light-emitting efficiencies.

S-ratios were calculated, and the results were shown in Table 3 in order to confirm a degree of improvement of luminous efficiency characteristics of the OLEDs manufactured in Examples 7 to 10 and Comparative Examples 5 to 7 according to luminance.

TABLE 3

| | Example | Example | Example | Example | Comparative | Comparative | Comparative |
|---|---|---|---|---|---|---|---|
| | 7 | 8 | 9 | 10 | Example 5 | Example 6 | Example 7 |
| Efficiency @ | 98.2 | 71.2 | 45.7 | 38.1 | 97.3 | 103.1 | 75.3 |
| 1 cd/m² | | | | | | | |
| Efficiency @ | 102.3 | 92.8 | 80.7 | 56.6 | 80.1 | 111.3 | 74.5 |
| 1,000 cd/m² | | | | | | | |
| S-ratio | 1.04 | 1.30 | 1.76 | 1.49 | 0.82 | 1.08 | 0.99 |

Referring to Table 3, unlike the S-ratios of the OLEDs manufactured in Examples 7 to 10 were all greater than 1 and 1.7 or greater in the case of Example 9, the S-ratios of the OLEDs manufactured in Comparative Examples 5 to 7 were around 1 or lower. That is, a shape of the luminance vs. efficiency graph of the OLEDs manufactured in Examples 7 to 10 is closer to S than that of the OLEDs manufactured in Comparative Examples 5 to 7.

In the regard, it may be confirmed that the OLEDs manufactured in Examples 7 to 10 have improved luminous efficiency characteristics according to luminance as the OLEDs show high green light-emitting efficiencies at a high luminance region and very low green light-emitting efficiencies at a low luminance region.

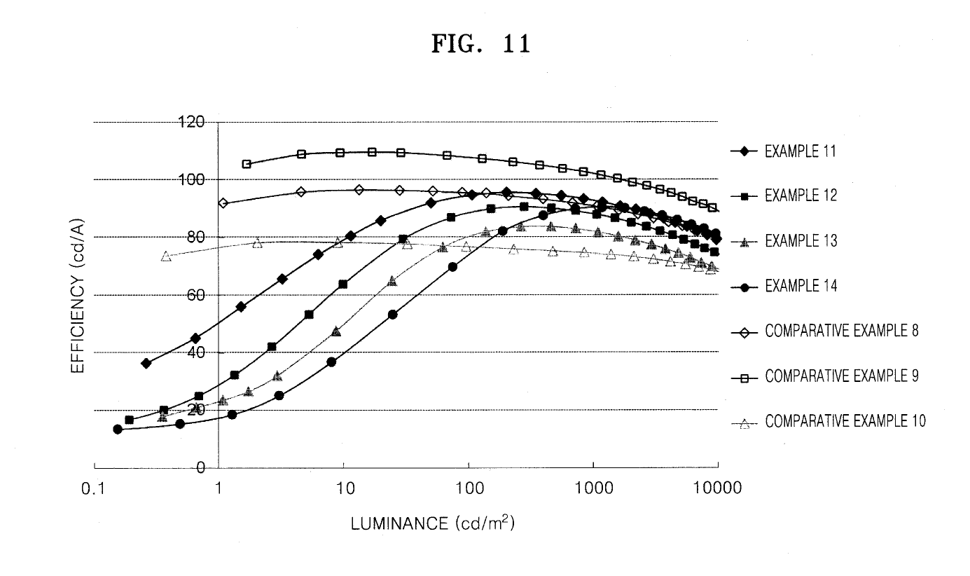

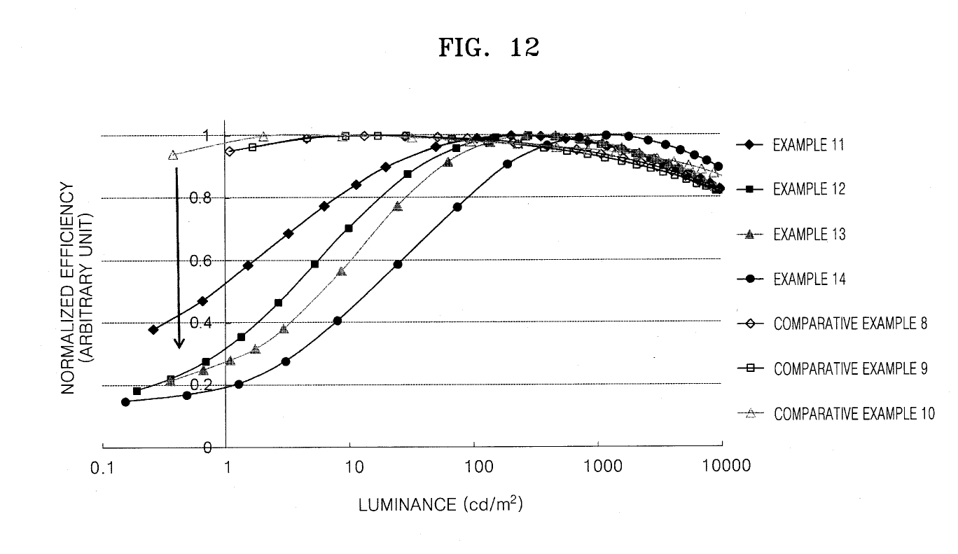

Green light-emitting efficiencies of the OLEDs manufactured according to Examples 11 to 14 and Comparative Examples 8 to 10 were measured while changing a luminance in a range from 0.1 cd/m² to 10,000 cd/m². The results were shown in FIG. 11, and the normalized results were shown in FIG. 12.

Referring to FIG. 11, the OLEDs manufactured in Examples 11 to 14 generally showed lower light-emitting efficiencies than the OLEDs manufactured in Comparative Example 8 to 10 at a low luminance.

Referring to FIG. 12 which is a normalized graph of a graph in FIG. 11, the OLEDs manufactured in Examples 11 to 14 showed similar levels of light-emitting efficiencies with the OLEDs manufactured in Comparative Examples 8 to 10 at a high luminance region of about 100 cd/m² or higher. However, the OLEDs manufactured in Examples 11 to 14 showed very low level of light-emitting efficiencies compared to the OLEDs manufactured in Comparative Examples 8 to 10 at a low luminance region of around about 1 cd/m². An arrow on the graph is to indicate reduction of light-emitting efficiencies.

S-ratios were calculated, and the results were shown in Table 4 in order to confirm a degree of improvement of luminous efficiency characteristics of the OLEDs manufactured in Examples 11 to 14 and Comparative Examples 8 to 10 according to luminance.

TABLE 4

| | Example | Example | Example | Example | Comparative | Comparative | Comparative |
|---|---|---|---|---|---|---|---|
| | 11 | 12 | 13 | 14 | Example 8 | Example 9 | Example 10 |
| Efficiency @ | 49.5 | 28.5 | 23.0 | 17.00 | 91.54 | 104.13 | 75.30 |
| 1 cd/m² | | | | | | | |
| Efficiency @ | 92.8 | 88.2 | 82.1 | 90.06 | 91.02 | 102.20 | 74.51 |
| 1,000 cd/m² | | | | | | | |
| S-ratio | 1.88 | 3.1 | 3.57 | 5.30 | 0.99 | 0.98 | 0.99 |

Referring to Table 4, the S-ratios of the OLEDs manufactured in Examples 11 to 14 were all greater than 1, 3 or greater in the case of Examples 12 and 13, and particularly, 5 or greater in the case of Example 14. However, the S-ratios of the OLEDs manufactured in Comparative Examples 8 to 10 were 1 or lower. That is, a shape of the luminance vs. efficiency graph of the OLEDs manufactured in Examples 11 to 14 is closer to S than that of the OLEDs manufactured in Comparative Examples 8 to 10.

In the case of the OLEDs manufactured in Examples 11 to 14 had significantly greater values of the S-ratios than other cases. This is considered as caused due to using a mixture of Compound 504, which is a bipolar compound having both a hole transport unit and an electron transport unit, and Compound 509 which is a compound having a hole transport unit as a host material.

In this regard, it may be confirmed that the OLEDs manufactured in Examples 11 to 14 have improved luminous efficiency characteristics according to luminance as the OLEDs show high red light-emitting efficiencies at a high luminance region and very low red light-emitting efficiencies at a low luminance region. A full color organic light-emitting display apparatus including red light-emitting devices, green light-emitting devices, and blue light-emitting devices has a high light-emitting efficiencies at a high luminance region and has an excellent luminous efficiency characteristics as emitting red and green light is suppressed in a black state.

As described above, an OLED according to an embodiment has improved luminous efficiency characteristics according to luminance by having an excellent luminous efficiency at a high luminance region and a low luminous efficiency at a low luminance region as the OLED includes an electron control layer and controls a flow of electrons that are injected to an emission layer.

An OLED according to another embodiment has improved luminous efficiency characteristics according to luminance by having an excellent luminous efficiency at a high luminance region and a low luminous efficiency at a low luminance region as the OLED includes an electron control layer and an electron blocking layer, and controls a flow of electrons that are injected to an emission layer.

An organic light-emitting display apparatus according to another embodiment has improved luminous efficiency characteristics according to luminance by including the OLED and suppressing emission of red and green light in the black state.

While the present embodiments have been particularly shown and described with reference to example embodiments thereof, it will be understood by those of ordinary skill in the art that various changes in form and details may be made therein without departing from the spirit and scope of the present embodiments as defined by the following claims.

What is claimed is:

1. An organic light-emitting device (OLED) comprising:
a first electrode;
a second electrode opposite to the first electrode;
a phosphorescent layer disposed between the first electrode and the second electrode;
an electron transport layer disposed between the phosphorescent emission layer and the second electrode; and
an electron control layer disposed between the phosphorescent emission layer and the electron transport layer,
wherein the phosphorescent emission layer comprises a host material and a dopant material, and the electron control layer comprises an electron control material, wherein a highest occupied molecular orbital (HOMO) energy level of the host material (EH_{H}), a lowest unoccupied molecular orbital (LUMO) energy level of the host material (EL_{H}), a HOMO energy level of the electron control material (EH_{C}), and a LUMO energy level of the electron control material (EL_{C}) satisfy both relationships of |EH_{H}−EH_{C}|≦0.3 eV and |EL_{H}−EL_{C}|≦0.5 eV, wherein a thickness of the electron control layer is from about 50 Å to about 450 Å.

2. The OLED of claim 1, wherein EH_{H}, EL_{H}, EH_{C}, and EL_{C} satisfy both relationships of 0≦EH_{H}−EH_{C}≦0.3 eV and 0≦EL_{H}−EL_{C}≦0.5 eV.

3. The OLED of claim 1, wherein an electron mobility of the electron control material is greater than or equal to the hole mobility of the electron control material.

4. The OLED of claim 1, wherein EH_{C} is from about −5.2 eV to about −6.1 eV.

5. The OLED of claim 1, wherein EL_{C} is from about −2.5 eV to about −3.2 eV.

6. The OLED of claim 1, wherein the content of the electron control material is from about 30 weight % (wt %) to about 100 wt % based on a total weight of the electron control layer.

7. The OLED of claim 1, wherein the thickness ratio of the electron transport layer and the electron control layer is from about 5:1 to about 5:10.

8. An OLED comprising:
a first electrode;
a second electrode opposite to the first electrode;
a phosphorescent layer disposed between the first electrode and the second electrode;
an electron transport layer disposed between the phosphorescent emission layer and the second electrode;
an electron control layer disposed between the phosphorescent emission layer and the electron transport layer; and
an electron blocking layer disposed between the phosphorescent emission layer and the first electrode,
wherein the phosphorescent emission layer comprises a host material and a dopant material, the electron control layer comprises an electron control material, and the electron blocking layer comprises an electron blocking material, wherein EH_{H}, EL_{H}, EH_{C}, EL_{C} and a LUMO energy level of the electron blocking material EL_{B} satisfy relationships of |EH_{H}−EH_{C}|≦0.3 eV, |EL_{H}−EL_{C}|≦0.5 eV, and EL_{B}>EL_{H}, wherein the thickness of the electron control layer is from about 50 Å to about 450 Å.

9. The OLED of claim 8, wherein the electron blocking material comprises at least one of a triphenylamine derivative, a carbazole derivative, and a spirobifluorene derivative.

10. The OLED of claim 8, wherein a thickness of the electron blocking layer is from about 10 Å to about 1000 Å.

11. The OLED of claim 8, wherein EH_{H}, EL_{H}, EH_{C}, and EL_{C} satisfy relationships of 0≦EH_{H}−EH_{C}≦0.3 eV and 0≦EL_{H}−EL_{C}≦0.5 eV.

12. The OLED of claim 8, wherein the electron mobility of the electron control material is greater than or equal to the hole mobility of the electron control material.

13. The OLED of claim 8, wherein EH_{C} is in a range from −5.2 eV to −6.1 eV.

14. The OLED of claim 8, wherein EL_{C} is in a range from −2.5 eV to −3.2 eV.

15. The OLED of claim 8, wherein the content of the electron control material is from about 30 wt % to about 100 wt % based on a total weight of the electron control layer.

16. The OLED of claim 8, wherein the thickness ratio of the electron transport layer and the electron control layer is in a range from about 5:1 to about 5:10.

17. The OLED of claim 1, wherein the electron control material comprises a compound represented by Formula 1 below: 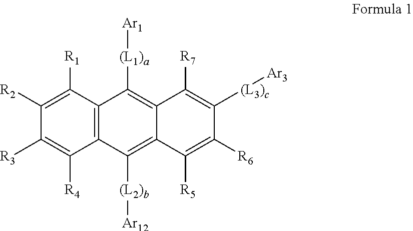
wherein R₁ to R₇ are each independently one of a hydrogen, a deuterium, a halogen, a hydroxy group, a cyano group, a nitro group, an amino group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, and a substituted or unsubstituted C₆-C₃₀ aryl group,
Ar₁, Ar₂, and Ar₃ are each independently one of a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₂-C₃₀ heteroaryl group, and a group represented by —N(Q₁)(Q₂), wherein at least one of Ar₁, Ar₂, and Ar₃ is a substituted or unsubstituted C₂-C₃₀ heteroaryl group, wherein Q₁ and Q₂ are each independently one of a hydrogen, a deuterium, a halogen, a hydroxy group, a cyano group, an amino group, a nitro group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₆-C₃₀ aryl group, a substituted or unsubstituted C₆-C₃₀ aryloxy group, a substituted or unsubstituted C₆-C₃₀ arylthio group, and a substituted or unsubstituted C₂-C₃₀ heteroaryl group,
L₁, L₂, and L₃ are each independently one of a substituted or unsubstituted C₆-C₃₀ arylene group, and a substituted or unsubstituted C₂-C₃₀ heteroarylene group, and
a, b, and c are each independently one of integers of 0 to 3.

18. The OLED of claim 1, wherein the electron control material comprises at least one compound represented by Formulae 2 and 3 below: 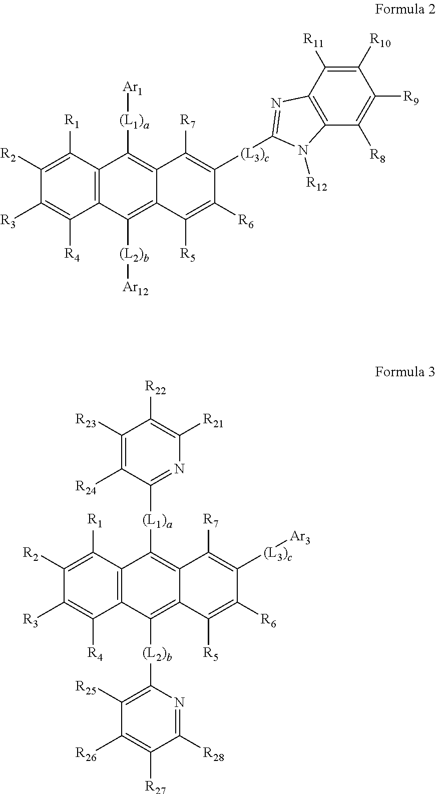
wherein In Formulae 2 and 3, R₁ to R₁₂ and R₂₁ to R₂₈ are each independently one of a hydrogen, a deuterium, a substituted or unsubstituted methyl group, a substituted or unsubstituted ethyl group, a substituted or unsubstituted propyl group, a substituted or unsubstituted butyl group, a substituted or unsubstituted phenyl group, a substituted or unsubstituted biphenyl group, a substituted or unsubstituted naphthyl group, a substituted or unsubstituted anthryl, a substituted or unsubstituted phenanthrenyl, a substituted or unsubstituted pyrenyl group,
Ar₁, Ar₂, and Ar₃ are each independently one of a substituted or unsubstituted phenyl group, a substituted or unsubstituted pentalenyl group, a substituted or unsubstituted indenyl group, a substituted or unsubstituted naphtyl group, a substituted or unsubstituted azulenyl group, a substituted or unsubstituted heptalenyl group, a substituted or unsubstituted indacenyl group, a substituted or unsubstituted acenaphtyl group, a substituted or unsubstituted fluorenyl group, a substituted or unsubstituted spirofluorenyl group, a substituted or unsubstituted phenalenyl group, a substituted or unsubstituted phenanthrenyl group, a substituted or unsubstituted anthryl group, a substituted or unsubstituted fluoranthenyl group, a substituted or unsubstituted triphenylenyl group, a substituted or unsubstituted pyrenyl group, a substituted or unsubstituted chrysenyl group, a substituted or unsubstituted naphthacenyl group, a substituted or unsubstituted picenyl group, a substituted or unsubstituted perylenyl group, a substituted or unsubstituted pentaphenyl group, a substituted or unsubstituted hexacenyl group, a substituted or unsubstituted pyrrolyl group, a substituted or unsubstituted imidazolyl group, a substituted or unsubstituted pyrazolyl group, a substituted or unsubstituted pyridinyl group, a substituted or unsubstituted bipyridinyl group, a substituted or unsubstituted pyrazinyl group, a substituted or unsubstituted pyrimidinyl group, a substituted or unsubstituted pyridazinyl group, a substituted or unsubstituted isoindolyl group, a substituted or unsubstituted indolyl group, a substituted or unsubstituted indazolyl group, substituted or unsubstituted purinyl group, a substituted or unsubstituted quinolinyl group, a substituted or unsubstituted benzoquinolinyl group, a substituted or unsubstituted phthalazinyl group, a substituted or unsubstituted naphthyridinyl group, a substituted or unsubstituted quinoxalinyl group, a substituted or unsubstituted quinazolinyl group, a substituted or unsubstituted cinnolinyl group, a substituted or unsubstituted carbazolyl group, a substituted or unsubstituted phenanthridinyl group, a substituted or unsubstituted acridinyl group, a substituted or unsubstituted phenanthrolinyl group, a substituted or unsubstituted phenazinyl group, a substituted or unsubstituted benzooxazolyl group, a substituted or unsubstituted benzoimidazolyl group, a substituted or unsubstituted furanyl group, a substituted or unsubstituted benzofuranyl group, a substituted or unsubstituted thiophenyl group, a substituted or unsubstituted benzothiophenyl group, a substituted or unsubstituted thiazolyl group, a substituted or unsubstituted isothiazolyl group, a substituted or unsubstituted benzothiazolyl group, a substituted or unsubstituted isoxazolyl group, a substituted or unsubstituted oxazolyl group, a substituted or unsubstituted triazolyl group, a substituted or unsubstituted tetrazolyl group, a substituted or unsubstituted oxadiazolyl group, a substituted or unsubstituted triazinyl group, a substituted or unsubstituted benzooxazolyl group, a substituted or unsubstituted dibenzopuranyl group, a substituted or unsubstituted dibenzothiophenyl group, and a substituted or unsubstituted bezocarbazolyl group,
L₁, L₂, and L₃ are each independently one of a substituted or unsubstituted phenylene group, a substituted or unsubstituted pentalenylene group, a substituted or unsubstituted indenylene group, a substituted or unsubstituted naphthylene group, a substituted or unsubstituted azulenylene group, a substituted or unsubstituted heptalenylene group, a substituted or unsubstituted indacenylene group, a substituted or unsubstituted acenaphthylene group, a substituted or unsubstituted fluorenylene group, a substituted or unsubstituted phenalenylene group, a substituted or unsubstituted phenanthrenylene group, a substituted or unsubstituted anthrylene group, a substituted or unsubstituted fluoranthenylene group, a substituted or unsubstituted triphenylenylene group, a substituted or unsubstituted pyrenylene group, a substituted or unsubstituted chrysenylene group, a substituted or unsubstituted naphthacenylene group, a substituted or unsubstituted picenylene group, a substituted or unsubstituted perylenylene group, a substituted or unsubstituted pentaphenylene group, a substituted or unsubstituted hexacenylene group, a substituted or unsubstituted pyrrolylene group, a substituted or unsubstituted pyrazolylene group, a substituted or unsubstituted imidazolylene group, a substituted or unsubstituted imidazolinylene group, a substituted or unsubstituted imidazopyridinylene group, a substituted or unsubstituted imidazopyrimidinylene group, a substituted or unsubstituted pyridinylene group, a substituted or unsubstituted pyrazinylene group, a substituted or unsubstituted pyrimidinylene group, a substituted or unsubstituted indolylene group, a substituted or unsubstituted purinylene group, a substituted or unsubstituted quinolinylene group, a substituted or unsubstituted phthalazinylene group, a substituted or unsubstituted indolizinylene group, a substituted or unsubstituted naphthyridinylene group, a substituted or unsubstituted quinazolinylene group, a substituted or unsubstituted cinnolinylene group, a substituted or unsubstituted indazolylene group, a substituted or unsubstituted carbazolylene group, a substituted or unsubstituted phenazinylene group, a substituted or unsubstituted phenanthridinylene group, a substituted or unsubstituted pyranylene group, a substituted or unsubstituted chromenylene group, a substituted or unsubstituted furanylene group, a substituted or unsubstituted benzofuranylene group, a substituted or unsubstituted thiophenylene group, a substituted or unsubstituted benzothiophenylene group, a substituted or unsubstituted isothiazolylene group, a substituted or unsubstituted benzoimidazolylene group, a substituted or unsubstituted isoxazolylene group, a substituted or unsubstituted dibenzothiophenylene group, a substituted or unsubstituted dibenzopuranylene group, a substituted or unsubstituted triazinylene group, and a substituted or unsubstituted oxadiazolylene group, and
a, b, and c are each independently one of integers of 0 to 1.

19. The OLED of claim 1, wherein the electron control material comprises at least one of Compounds 1 and 2 below:

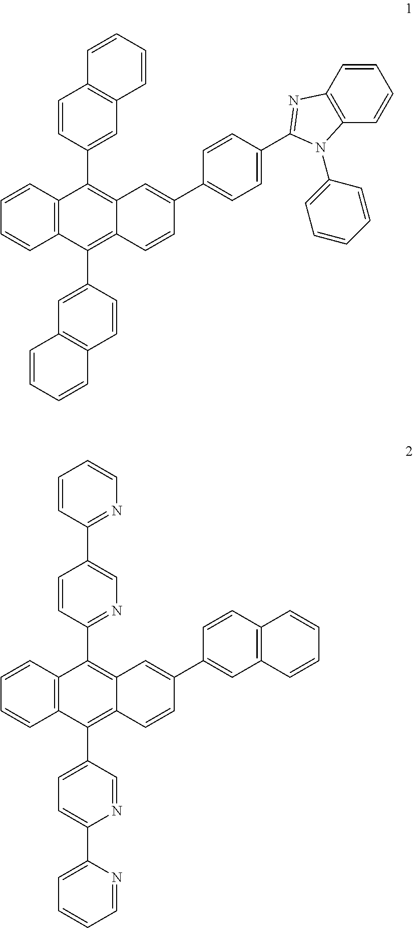 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc(-c3c4ccccc4c(-c4ccc(-c5ccccn5)nc4)c4ccc(-c5ccc6ccccc6c5)cc34)nc2)nc1]

20. The OLED of claim 1, wherein the host material comprises a bipolar compound having both of a hole transport unit and an electron transport unit.

21. The OLED of claim 1, wherein the host material comprises a mixture of a bipolar compound having both of a hole transport unit and an electron transport unit and a compound having at least a hole transport unit.

22. The OLED of claim 1, wherein the phosphorescent emission layer emits red or green light.

23. The OLED of claim 1, wherein the electron transport layer comprises a compound represented by Formula 4 below: 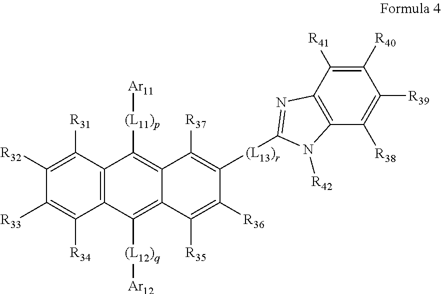
wherein R₃₁ to R₄₂ are each independently one of a hydrogen, a deuterium, a substituted or unsubstituted methyl group, a substituted or unsubstituted ethyl group, a substituted or unsubstituted propyl group, a substituted or unsubstituted butyl group, a substituted or unsubstituted phenyl group, a substituted or unsubstituted biphenyl group, a substituted or unsubstituted naphthyl group, a substituted or unsubstituted anthryl, a substituted or unsubstituted phenanthrenyl, a substituted or unsubstituted pyrenyl group,
Ar₁₁ and Ar₁₂ are each independently one of a substituted or unsubstituted phenyl group, a substituted or unsubstituted pentalenyl group, a substituted or unsubstituted indenyl group, a substituted or unsubstituted naphtyl group, a substituted or unsubstituted azulenyl group, a substituted or unsubstituted heptalenyl group, a substituted or unsubstituted indacenyl group, a substituted or unsubstituted acenaphtyl group, a substituted or unsubstituted fluorenyl group, a substituted or unsubstituted spirofluorenyl group, a substituted or unsubstituted phenalenyl group, a substituted or unsubstituted phenanthrenyl group, a substituted or unsubstituted anthryl group, a substituted or unsubstituted fluoranthenyl group, a substituted or unsubstituted triphenylenyl group, a substituted or unsubstituted pyrenyl group, a substituted or unsubstituted chrysenyl group, a substituted or unsubstituted naphthacenyl group, a substituted or unsubstituted picenyl group, a substituted or unsubstituted perylenyl group, a substituted or unsubstituted pentaphenyl group, a substituted or unsubstituted hexacenyl group, a substituted or unsubstituted pyrrolyl group, a substituted or unsubstituted imidazolyl group, a substituted or unsubstituted pyrazolyl group, a substituted or unsubstituted pyridinyl group, a substituted or unsubstituted bipyridinyl group, a substituted or unsubstituted pyrazinyl group, a substituted or unsubstituted pyrimidinyl group, a substituted or unsubstituted pyridazinyl group, a substituted or unsubstituted isoindolyl group, a substituted or unsubstituted indolyl group, a substituted or unsubstituted indazolyl group, a substituted or unsubstituted purinyl group, a substituted or unsubstituted quinolinyl group, a substituted or unsubstituted benzoquinolinyl group, a substituted or unsubstituted phthalazinyl group, a substituted or unsubstituted naphthyridinyl group, a substituted or unsubstituted quinoxalinyl group, a substituted or unsubstituted quinazolinyl group, a substituted or unsubstituted cinnolinyl group, a substituted or unsubstituted carbazolyl group, a substituted or unsubstituted phenanthridinyl group, a substituted or unsubstituted acridinyl group, a substituted or unsubstituted phenanthrolinyl group, a substituted or unsubstituted phenazinyl group, a substituted or unsubstituted benzooxazolyl group, a substituted or unsubstituted benzoimidazolyl group, a substituted or unsubstituted furanyl group, a substituted or unsubstituted benzofuranyl group, a substituted or unsubstituted thiophenyl group, a substituted or unsubstituted benzothiophenyl group, a substituted or unsubstituted thiazolyl group, a substituted or unsubstituted isothiazolyl group, a substituted or unsubstituted benzothiazolyl group, a substituted or unsubstituted isoxazolyl group, a substituted or unsubstituted oxazolyl group, a substituted or unsubstituted triazolyl group, a substituted or unsubstituted tetrazolyl group, a substituted or unsubstituted oxadiazolyl group, a substituted or unsubstituted triazinyl group, a substituted or unsubstituted benzooxazolyl group, a substituted or unsubstituted dibenzopuranyl group, a substituted or unsubstituted dibenzothiophenyl group, and a substituted or unsubstituted bezocarbazolyl group,
L₁₁, L₁₂, and L₁₃ are each independently one of a substituted or unsubstituted phenylene group, a substituted or unsubstituted pentalenylene group, a substituted or unsubstituted indenylene group, a substituted or unsubstituted naphthylene group, a substituted or unsubstituted azulenylene group, a substituted or unsubstituted heptalenylene group, a substituted or unsubstituted indacenylene group, a substituted or unsubstituted acenaphthylene group, a substituted or unsubstituted fluorenylene group, a substituted or unsubstituted phenalenylene group, a substituted or unsubstituted phenanthrenylene group, a substituted or unsubstituted anthrylene group, a substituted or unsubstituted fluoranthenylene group, a substituted or unsubstituted triphenylenylene group, a substituted or unsubstituted pyrenylene group, a substituted or unsubstituted chrysenylene group, a substituted or unsubstituted naphthacenylene group, a substituted or unsubstituted picenylene group, a substituted or unsubstituted perylenylene group, a substituted or unsubstituted pentaphenylene group, a substituted or unsubstituted hexacenylene group, a substituted or unsubstituted pyrrolylene group, a substituted or unsubstituted pyrazolylene group, a substituted or unsubstituted imidazolylene group, a substituted or unsubstituted imidazolinylene group, a substituted or unsubstituted imidazopyridinylene group, a substituted or unsubstituted imidazopyrimidinylene group, a substituted or unsubstituted pyridinylene group, a substituted or unsubstituted pyrazinylene group, a substituted or unsubstituted pyrimidinylene group, a substituted or unsubstituted indolylene group, a substituted or unsubstituted purinylene group, a substituted or unsubstituted quinolinylene group, a substituted or unsubstituted phthalazinylene group, a substituted or unsubstituted indolizinylene group, a substituted or unsubstituted naphthyridinylene group, a substituted or unsubstituted quinazolinylene group, a substituted or unsubstituted cinnolinylene group, a substituted or unsubstituted indazolylene group, a substituted or unsubstituted carbazolylene group, a substituted or unsubstituted phenazinylene group, a substituted or unsubstituted phenanthridinylene group, a substituted or unsubstituted pyranylene group, a substituted or unsubstituted chromenylene group, a substituted or unsubstituted furanylene group, a substituted or unsubstituted benzofuranylene group, a substituted or unsubstituted thiophenylene group, a substituted or unsubstituted benzothiophenylene group, a substituted or unsubstituted isothiazolylene group, a substituted or unsubstituted benzoimidazolylene group, a substituted or unsubstituted isoxazolylene group, a substituted or unsubstituted dibenzothiophenylene group, a substituted or unsubstituted dibenzopuranylene group, a substituted or unsubstituted triazinylene group, and a substituted or unsubstituted oxadiazolylene group, and
p, q, and r are each independently an integer of 0 to 1.

24. The OLED of claim 23, wherein the electron transport layer further comprises at least one selected from a lithium quinolate (LiQ) and Compound 101 below:

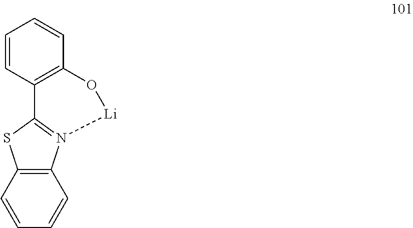

25. The OLED of claim 23, wherein the electron transport layer 373 further comprises at least one selected from 1,4,5,8,9,12-hexaazatriphenylene hexacarbonitrile, tetracyanoquinodimethane, anthraquinone, perylenebisimide, and tetracyanoanthraquinodimethane.

26. The OLED of claim 23, wherein the electron transport layer further comprises at least one selected from at least one metal selected from Li, Cs, Na, K, Ca, Mg, Ba, and Ra; metal carbonate; metal acetate; metal benzoate; metal acetoacetate; metal acetylacetonate; and metal stearate.

27. The OLED of claim 1, wherein the OLED further comprises a hole transport layer disposed between the phosphorescent emission layer and the first electrode, wherein the hole transport layer comprises a compound represented by Formula 5 below: 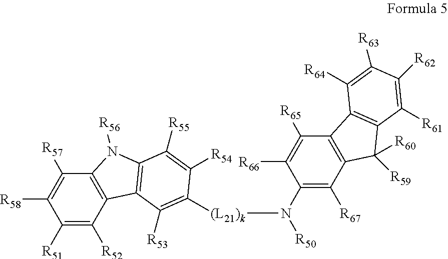
wherein R₅₀ is one of a substituted or unsubstituted phenyl group, a substituted or unsubstituted naphthyl group, a substituted or unsubstituted anthryl group, a substituted or unsubstituted biphenyl group, and a substituted or unsubstituted pyridyl group;
L₂₁ is one of a substituted or unsubstituted C₁-C₃₀ alkylene group, a substituted or unsubstituted C₂-C₃₀ alkenylene group, a substituted or unsubstituted C₆-C₃₀ arylene group, and a substituted or unsubstituted C₂-C₃₀ heteroarylene group;
R₅₁ to R₆₇ are each independently one of a hydrogen, a deuterium, a halogen, a hydroxy group, a cyano group, a nitro group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthiol group, a substituted or unsubstituted C₃-C₃₀ cycloalkyl group, a substituted or unsubstituted C₃-C₃₀ cycloalkenyl group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₂-C₃₀ heteroaryl group, and a group represented by —N(Q₁₁)(Q₁₂); Q₁₁ and Q₁₂ are each independently one of a hydrogen, a deuterium, a halogen, a hydroxy group, a cyano group, an amino group, a nitro group, a carboxyl group, a C₁-C₃₀ alkyl group, a C₂-C₃₀ alkenyl group, a C₂-C₃₀ alkynyl group, a C₁-C₃₀ alkoxy group, a C₁-C₃₀ alkylthiol group, a C₃-C₃₀ cycloalkyl group, a C₃-C₃₀ cycloalkenyl group, a C₆-C₃₀ aryl group, a C₆-C₃₀ aryloxy group, a C₆-C₃₀ arylthio group, and a C₂-C₃₀ heteroaryl group; and
k is one of integers of 0 to 3.

28. The OLED of claim 27, wherein the OLED further comprises a hole injection layer disposed between the hole transport layer and the first electrode, wherein the hole injection layer comprises a compound represented by Formula 6 below: 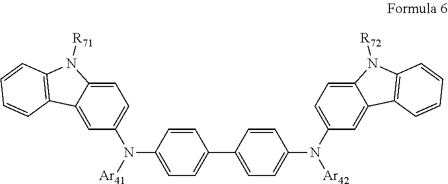
wherein Ar₄₁ and Ar₄₂ are each independently one of a substituted or unsubstituted C₆-C₃₀ arylene group and a substituted or unsubstituted C₂-C₃₀ heteroarylene group, R₇₁ and R₇₂ are each independently one of a hydrogen, a deuterium, a halogen, a hydroxy group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₆-C₃₀ aryl group, a substituted or unsubstituted C₆-C₃₀ aryloxy group, and a substituted or unsubstituted C₆-C₃₀ arylthio group.

29. An organic light-emitting display apparatus comprising a transistor comprising source, drain, gate, and an active layer, and the OLED of claim 1, wherein a first electrode of the OLED is electrically connected to the source or the drain.
